(19) United States
(12) Patent Application Publication
(10) Pub. No.: US 2026/0371736 A1
(43) Pub. Date: Nov. 19, 2026

(54) INTEGRATED CIRCUIT AND ASSOCIATED METHOD OF MANUFACTURE

(71) Applicant: Pragmatic Semiconductor Limited, Cambridge (GB)

(72) Inventors: Richard PRICE, Sedgefield, Durham (GB); Feras ALKHALIL, Sedgefield, Durham (GB); Niels VAN FRAASSEN, Sedgefield, Durham (GB)

(73) Assignee: Pragmatic Semiconductor Limited, Cambridge (GB)

(21) Appl. No.: 19/133,736

(22) PCT Filed: Nov. 29, 2023
(86) PCT No.: PCT/GB2023/053083

§ 371 Date: May 29, 2025

(30) Foreign Application Priority Data
Nov. 29, 2022 (GB) 2217962.6

(51) Int. Cl. H10D 86/40; H10D 86/01

(52) U.S. Cl. CPC H10D 86/471; H10D 86/0223; H10D 86/423; H10D 86/431

(57) ABSTRACT

An integrated circuit (IC) is disclosed that comprises at least one p-type thin film transistor, ‘TFT’, and at least one further electronic device, formed from a plurality of layers fabricated on a substrate. The at least one p-type TFT comprises a channel region formed from at least partially crystalline silicon. The partially crystalline silicon may comprise low temperature polycrystalline silicon (LTPS). The channel region of the at least one p-type TFT may be formed of at least partially crystalline silicon that has a charge carrier mobility within the range of 1 to 40 cm2/V·s inclusive. The at least one further electronic device may comprise at least one n-type TFT having a channel region formed from semiconducting oxide.

The present disclosure relates to integrated circuits (ICs), and methods for the manufacture of such ICs. The present invention relates in particular, but is not limited to, integrated circuits comprising one or more p-type thin-film transistors (TFT), and associated methods of manufacturing integrated circuits comprising one or more p-type TFTs.

Historically, the manufacture of ICs has heavily involved using a single crystalline wafer of semiconductor material such as Silicon (c-Si) or Gallium arsenide (GaAs) as a substrate on which microelectronic circuits were fabricated to form the ICs. Such wafers typically have an extreme level of purity and, by virtue of their single crystal structure, exhibit relatively high charge mobilities compared to non-crystalline semiconductors.

During the manufacturing process devices such as diodes, transistors, capacitors, and resistors, are typically built up by forming p-type, n-type, and/or undoped semiconductor regions, in the semiconductor substrate using appropriate doping, and/or by forming other features using other materials (e.g., insulating/dielectric and/or conducting material), using appropriate fabrication processes. The location of the n-type, p-type, and/or undoped regions and the pattern of insulating and/or conducting material in each layer defining the devices, and the interconnectivity between them, is typically defined using appropriate photolithographic processes.

One of the fundamental electronic components that typically forms part of such integrated circuits, especially for logic circuits and other digital electronic applications, is the so called field-effect transistor (FET). An FET may, for example, be employed in a wide range of circuits as a voltage controlled switch and/or as a voltage controlled resistor. An FET generally comprises three terminals—a source, a drain, and a gate. The gate typically comprises a conductive gate electrode, formed on a layer of insulator (dielectric) material that is provided on a semiconductor material between the source and the drain. An electric field arising from a voltage applied to the gate causes the formation of, and or modulates the conductivity of, a conductive channel beneath the gate (typically at the interface between the insulator and the semiconductor) in a channel region that extends from the source to the drain and thus allows a current to flow. Where the semiconductor material below the gate of a device is undoped, or doped positive, and a positive gate voltage is required to form a channel of negative charge (electrons)—such devices may be referred to as ‘n-type’, or ‘n-channel’, devices. Where the semiconductor material below the gate of a device is undoped, or doped negative, and a negative gate voltage is required to form a channel of positive charge (referred to as holes)—such devices may be referred to as ‘p-type’, or ‘p-channel’, devices.

Such FETs may be referred to in a number of different ways, for example as: metal-insulator-semiconductor FETs (MISFETS); metal-oxide-semiconductor FETs (MOSFETS); metal-oxide-semiconductor transistors (MOSTs); or the like. It will be appreciated that the term MOSFET or MOST has become so widely used that it is also used to refer to devices that do not strictly have a metal-oxide-semiconductor structure (e.g., comprising a gate electrode that is not strictly a metal (e.g., a very heavily doped polysilicon) and/or a gate insulator that is not strictly an oxide (e.g., a nitride)).

Nevertheless, whilst the manufacture of MOSFETs on single crystal semiconductor substrates has wide application, there are also a wide range of applications for which it is beneficial to be able to manufacture FETs on other substrates including insulating substrates. For example, there are many applications for FETs fabricated on rigid substrates (e.g., formed of a rigid glass), or flexible substrates (e.g., formed of a layer of polymer based material). Flexible substrate based circuitry, in particular, has been emerging as an important technology for the fabrication of low-cost flexible ICs that can be embedded into everyday objects relatively easily.

A flexible circuit element or structure, such as, for example, a flexible integrated circuit (e.g., flexible IC or FlexIC), is a patterned arrangement of circuitry and components provided on a flexible base material with or without flexible overlay. The circuitry patterned on each flexible circuit element may comprise any of resistors, capacitors, transistors, diodes, inductors, conductors, etc. The flexible base material (or flexible substrate) may be a polymer layer.

In their simplest form, FETs fabricated on such substrates, comprise: a thin semiconducting layer provided on the substrate that acts as the channel region; conductive regions at either end of the channel region to act as the source and the drain; a thin layer of insulating material provided on the channel region to act as the gate dielectric; and a conductive material provided on the gate dielectric to act as the gate electrode. Because of the physical characteristics of these FETs they are generally referred to as thin film transistors (TFTs).

There are many different types of material that have been used in the thin semiconducting layer that acts as the channel region for TFTs including, for example: amorphous silicon (a-Si); microcrystalline (also referred to as nanocrystalline silicon) that comprises small crystals (typically of the order of a few nano-metres in size) embedded in an amorphous matrix; and polycrystalline silicon (also referred to as polysilicon or poly-Si) that is formed of silicon crystals (typically of the order of 1 μm in size) of different orientations. α-Si has the advantage that high quality, large-area α-Si films can be fabricated at low temperatures and relatively inexpensively (e.g., using plasma enhanced chemical vapor deposition (PECVD)). Hydrogenated, α-Si:H TFTs can also exhibit a relatively low off-state current which makes them particularly well suited to use as pixel switches for imaging arrays. α-Si has a relatively low carrier mobility which limits its application for high-speed switching and the like. Microcrystalline silicon, if fabricated correctly, is generally more stable than, and has a better mobility than α-Si:H and can be deposited relatively inexpensively in a similar fashion to α-Si. Polysilicon is characterised by significantly higher charge carrier mobilities and is much more stable than α-Si (albeit still much lower than for crystalline silicon), which makes polysilicon suitable for creating much more complex and high-speed TFT-based electronic circuits.

One way to form polysilicon involves solid phase crystallisation of a deposited layer of amorphous silicon by thermally annealing (traditionally at above 900 °C) the amorphous silicon to cause crystal formation at various orientations by nucleation and growth. However, many types of substrate on which it would be desirable to form TFTs are not resistant to such high temperatures and so techniques have been developed to form polysilicon for such TFTs at much lower temperatures (<~650 °C or even lower temperatures for flexible polymer based substrates). Polycrystalline silicon formed in this way is known, in the art, as low-temperature polycrystalline silicon (LTPS). Formation of LTPS typically involves, for example, deposition of α-Si at a relatively low temperature (<~400 °C) followed by crystallisation into polysilicon using an excimer (gas) or blue (diode) laser without (or with only minimal) heating of the substrate.

Whilst LTPS is relatively costly, and difficult to scale due to the need for laser annealing, TFTs fabricated using LTPS tend to have superior on-currents, which means that a smaller TFT can be used having a lower parasitic capacitance. The higher current, and lower parasitic capacitance both contribute to faster switching.

More recently, n-type ‘semiconducting oxide based’ TFTs have been developed which use indium gallium zinc oxide (IGZO) as the active layer. IGZO is an oxide based semiconducting material, consisting of a form of zinc oxide (ZnO) with added indium and gallium which allows this material to be deposited in a uniform amorphous phase on temperature sensitive substrates whilst maintaining the oxide's relatively high carrier mobility (typically 20 to 50 times that of α-Si). Moreover, oxide based technology has the significant advantage compared to both α-Si:H and LTPS of a very low off current. However, even though n-type oxide (e.g., IGZO) based TFTs show promise, p-type oxide (e.g., copper oxide(I) (Cu₂O), tin monoxide (SnO) or nickel oxide (NiO)) TFTs with the equivalent—or even sufficient—performance and TFT stability remains elusive. This means that oxide based TFTs are not suitable for applications for which circuits comprising complementary n-type and p-type TFTs (known as complementary metal-oxide-semiconductor or ‘CMOS’) are required.

It can be seen, therefore, that the various different techniques for implementing TFT based ICs have various different issues associated with them and that none of them are ideal. There is, therefore, a need for alternative techniques, and associated apparatus and/or devices, for implementing TFT based ICs that at least partially address or ameliorate one or more of the above conflicting issues.

The present invention aims to provide methods and apparatus/devices that at least partially contribute to meeting the above need.

Aspects of the invention are set out in the appended independent claims, other optional but beneficial features are set out in the appended dependent claims.

In one example described herein there is provided an integrated circuit (IC) comprising: at least one p-type thin film transistor, ‘TFT’, and at least one further electronic device, formed on a substrate; wherein the at least one p-type TFT comprises a channel region formed from at least partially crystalline silicon, wherein the partially crystalline silicon has been formed from amorphous silicon using a process that maintains the substrate at a temperature below 650 °C; and wherein, the channel region of the at least one p-type TFT is formed of at least partially crystalline silicon that has a charge carrier mobility within the range of 1 to 40 cm²/V·s

In one example described herein there is provided an integrated circuit (IC) comprising: at least one p-type thin film transistor, ‘TFT’, and at least one further electronic device, fabricated on a substrate; wherein the at least one p-type TFT comprises a channel region formed from at least partially crystalline silicon, wherein the partially crystalline silicon has been formed from amorphous silicon using a process that maintains the substrate at a temperature below 650 °C; and wherein the at least one further electronic device comprises at least one n-type TFT, wherein the at least one n-type TFT comprises a channel region formed from semiconducting oxide.

The at least one further electronic device may comprise at least one n-type TFT, wherein the at least one n-type TFT comprises a channel region formed from semiconducting oxide.

The channel region of the at least one p-type TFT may be formed of at least partially crystalline silicon that has a charge carrier mobility that is within a range of 1 to 20, optionally within a range of 1 to 10 or a range of 1 to 5, times a charge carrier mobility of the semiconducting oxide from which the channel region of the at least one n-type TFT is formed. The at least one p-type TFT may have a first channel length and the at least one n-type TFT may have a second channel length. The first channel length may be greater than the second channel length. The first channel length may be greater than 1 μm in length and the second channel length may be less than 1 μm in length. The second channel length may be less than 0.6 μm in length. A channel length, or the first channel length, of the at least one p-type TFT may be between 0.05 μm and 0.6 μm.

The first channel length and the second channel length may be mutually configured to ensure that a lowest value of a first maximum drain source current for a given gate voltage magnitude for the p-type device, and a second maximum drain source current for the given gate voltage magnitude for the n-type device is within 25% of the highest value of the first maximum drain source current and the second maximum drain source current. The first channel length and the second channel length may be mutually configured to ensure that the second maximum drain source current is the same as or greater than the second maximum drain source current.

The at least one p-type TFT may have a p-type TFT gate insulator, and the at least one n-type TFT may have an n-type TFT gate insulator that is formed of a different insulator layer to the first gate insulator. The p-type TFT gate insulator may be of a first thickness and the n-type TFT gate insulator may be of a second thickness that is different to the first thickness. The first thickness and second thickness may be mutually configured to ensure that a lowest value of a first parasitic capacitance associated with the p-type TFT gate insulator, and a second parasitic capacitance associated with the n-type TFT gate insulator, is within 20% of a highest value of the first parasitic capacitance and the second parasitic capacitance.

The p-type TFT first gate insulator may be of a first material having a first dielectric constant and the n-type TFT gate insulator may be of a second material having a second dielectric constant that is different to the first dielectric constant. The first material may have a first dielectric constant and the second material may have a second dielectric constant, and the first dielectric constant and the second dielectric constant may be mutually configured to ensure that a lowest value of a first parasitic capacitance associated with the p-type TFT gate insulator and a second parasitic capacitance associated with the n-type TFT gate insulator, is within 20% of a highest value of the first parasitic capacitance and the second parasitic capacitance.

The at least one further electronic device may comprise at least one resistor formed from a semiconducting oxide forming part of a fabrication layer that is common with the semiconducting oxide from which the channel region of the n-type TFT is formed.

The at least one p-type TFT and the at least one n-type TFT may have respective gate insulators that are formed of the same insulator layer. The at least one semiconducting oxide, from which the channel region of the n-type TFT is formed, may be provided directly on the substrate or on a barrier layer formed directly on the substrate. The at least one semiconducting oxide, from which the channel region of the n-type TFT is formed, may be formed on an insulating layer that is provided between the substrate and the at least one semiconducting oxide. A source region and a drain region of the at least one n-type TFT may be formed at either end of the channel region from the at least one semiconducting oxide. The source region and the drain region of the at least one n-type TFT may be formed from respective regions of the at least one semiconducting oxide that have been irradiated with electro-magnetic radiation to change an electrical property of those regions of the at least one semiconducting oxide to make the regions of the at least one semiconducting oxide conductive. The at least one semiconducting oxide may be a metal oxide semiconductor. The at least one semiconducting oxide may be indium gallium zinc oxide, ‘IGZO’.

The at least one p-type thin film transistor, ‘TFT’, and the at least one n-type thin film transistor are interconnected to form a circuit comprising at least one complementary metal oxide semiconductor, ‘CMOS’, circuit. The at least one CMOS circuit may comprise at least one CMOS inverter circuit. The at least partially crystalline silicon, from which the channel region of the p-type TFT is formed, may be formed directly on the substrate or on a barrier layer formed directly on the substrate. A source region and a drain region of the at least one p-type TFT may be formed at either end of the channel region from the at least partially crystalline silicon. The source region and the drain region of the at least one p-type TFT may be formed from respective regions of the at least partially crystalline silicon that have been irradiated with electro-magnetic radiation to change an electrical property of the partially crystalline silicon of those regions of the at least partially crystalline silicon to make those regions of the at least partially crystalline silicon more conductive. The source region and the drain region of the at least one p-type TFT may be formed from respective regions of the at least partially crystalline silicon that have been doped to change an electrical property of the partially crystalline silicon of those regions of the at least partially crystalline silicon to make those regions of the at least partially crystalline silicon more conductive. The at least partially crystalline silicon may comprise polycrystalline silicon. The polycrystalline silicon may be low temperature polycrystalline silicon, ‘LTPS’. The at least partially crystalline silicon may have been formed from amorphous silicon using a laser. The at least partially crystalline silicon may have been formed from amorphous silicon using an excimer laser, or a blue light-emitting diode (LED), or a blue solid state laser.

The at least one further electronic device may comprise at least one resistor. The at least one resistor may comprise at least one resistor formed from at least partially crystalline silicon. The at least one resistor may comprise at least one resistor formed from at least partially crystalline silicon forming part of a fabrication layer that is common with the at least partially crystalline silicon from which the channel region of the at least one p-type TFT is formed. The at least one resistor may comprise at least one resistor formed from a semiconducting oxide material.

The at least one further electronic device may comprise at least one capacitor comprising comprises a first capacitor plate, a second plate formed of metal, and a capacitor insulator provided between the first capacitor plate and the second capacitor plate. The at least one capacitor may comprise at least one capacitor for which the first capacitor plate is formed from a semiconductor material, and the second plate is formed of a metal material. The first capacitor plate may be formed from at least partially crystalline silicon that is of the same type as the at least partially crystalline silicon from which the channel region of the at least one p-type TFT is formed. The at least one capacitor may comprise at least one capacitor for which the first capacitor plate and the second plate are each formed of a respective metal material.

The substrate may be a flexible substrate. The substrate may be formed of polyimide. The substrate may be a rigid substrate. The substrate may be formed of glass. A barrier layer may be formed on the substrate.

In one example described herein there is provided a method of fabricating an integrated circuit (IC), the method comprising: providing a substrate and fabricating the IC on the substrate, the IC comprising at least one p-type thin film transistor, ‘TFT’, and at least one further electronic device; wherein the at least one p-type TFT is fabricated by: forming a first layer, the first layer comprising amorphous silicon; processing the first layer to convert the amorphous silicon into at least partially crystalline silicon using a process that maintains the substrate at a temperature below 650 °C; patterning the first layer, before or after conversion to the at least partially crystalline silicon, to form at least one semiconductor area; and fabricating the at least one p-type TFT wherein the channel region of the at least one p-type TFT is formed from the at least partially crystalline silicon of the at least one semiconductor area; wherein, the processing of the first layer is configured to produce partially crystalline silicon, in the at least one semiconductor area that forms the channel region of the at least one p-type TFT, that has a charge carrier mobility within the range of 1 to 40 cm²/V·s when the at least one p-type TFT has been fabricated.

In one example described herein there is provided a method of fabricating an integrated circuit (IC), the method comprising: providing a substrate and fabricating the IC on the substrate, the IC comprising at least one p-type thin film transistor, ‘TFT’, and at least one further electronic device; wherein the at least one p-type TFT is fabricated by: forming a first layer, the first layer comprising amorphous silicon; processing the first layer to convert the amorphous silicon into at least partially crystalline silicon using a process that maintains the substrate at a temperature below 650 °C; patterning the first layer, before or after conversion to the at least partially crystalline silicon, to form at least one semiconductor area; and fabricating the at least one p-type TFT wherein the channel region of the at least one p-type TFT is formed from the at least partially crystalline silicon of the at least one semiconductor area; wherein the at least one further electronic device comprises an n-type TFT, wherein the at least one n-type TFT is fabricated by: forming a second layer, the second layer comprising a semiconducting oxide; patterning the second layer to form at least one semiconducting oxide area; and fabricating the at least one n-type TFT wherein a channel region of the at least one n-type TFT is formed from the semiconducting oxide of the at least one semiconducting oxide area.

The at least one further electronic device may comprise an n-type TFT, wherein the at least one n-type TFT is fabricated by: forming a second layer, the second layer comprising a semiconducting oxide; patterning the second layer to form at least one semiconducting oxide area; and fabricating the at least one n-type TFT wherein a channel region of the at least one n-type TFT is formed from the semiconducting oxide of the at least one semiconducting oxide area.

The processing of the first layer may be configured to produce partially crystalline silicon, in the at least one semiconductor area that forms the channel region of the at least one p-type TFT, that has a charge carrier mobility that is within a range of 1 to 20, optionally within a range of 1 to 10 or a range of 1 to 5, times a charge carrier mobility of the semiconducting oxide from which the channel region of the at least one n-type TFT is formed.

The at least one p-type thin film transistor, ‘TFT’, and the at least one n-type thin film transistor may be interconnected to form a circuit comprising at least one complementary metal oxide semiconductor, ‘CMOS’, circuit. The at least one CMOS circuit may comprise at least one CMOS inverter circuit.

In one example described herein there is provided a method of fabricating an integrated circuit (IC), the method comprising providing a substrate and fabricating any IC as described above on the substrate from a plurality of layers.

Examples of various integrated circuits and associated manufacturing processes will now be described, by way of example only, with reference to the accompanying drawings, in which:

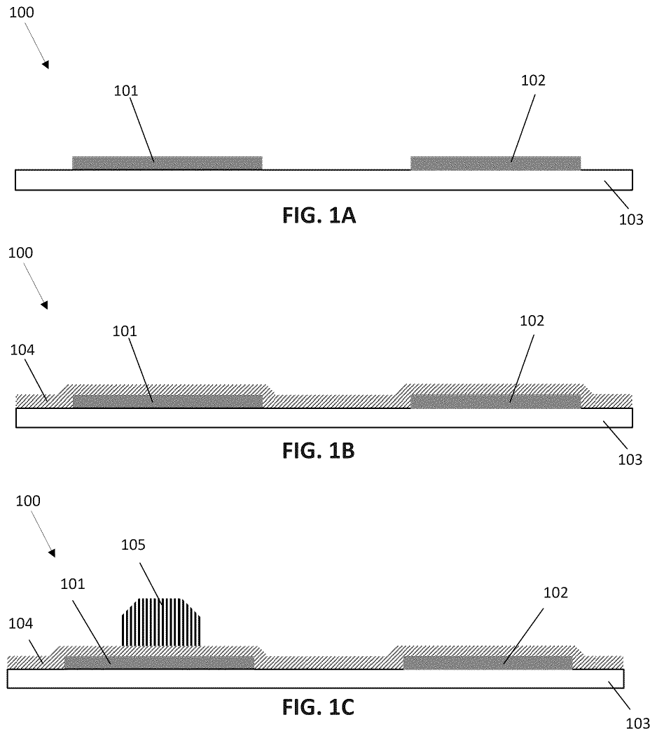

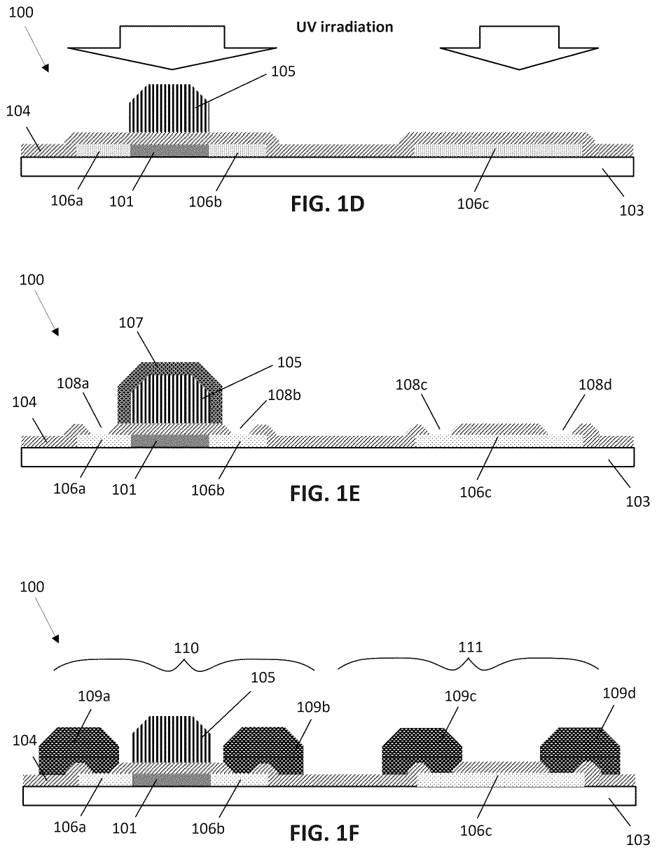

FIGS. 1A to 1F illustrate a method for manufacturing an integrated electronic circuit comprising a low temperature polysilicon (LTPS) p-type thin film transistor (TFT) in conjunction with a resistor;

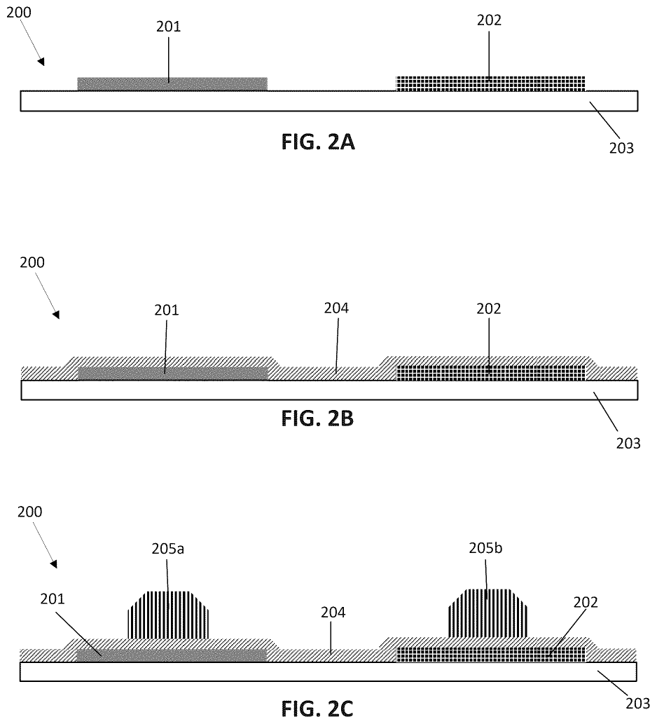

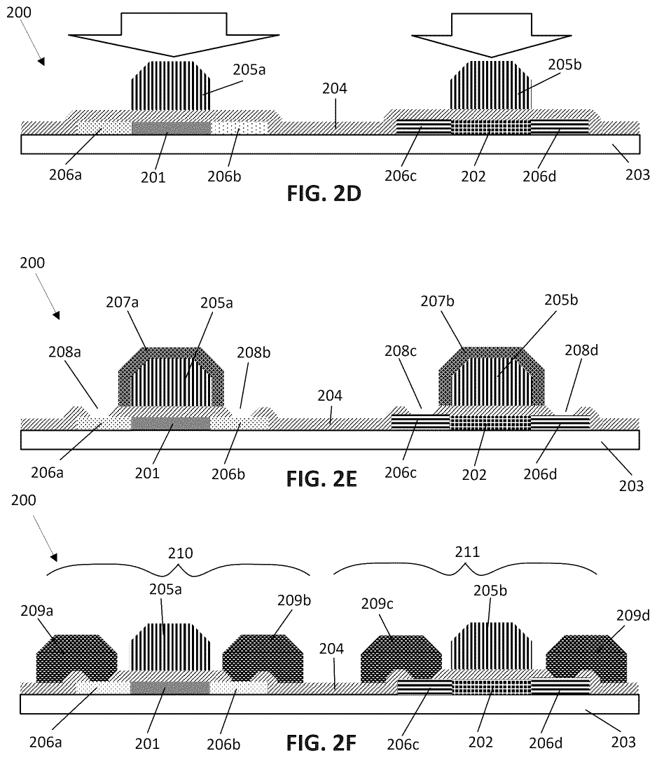

FIGS. 2A to 2F illustrate a method for manufacturing an integrated electronic circuit comprising an LTPS p-type TFT in conjunction with a first type of n-type TFT;

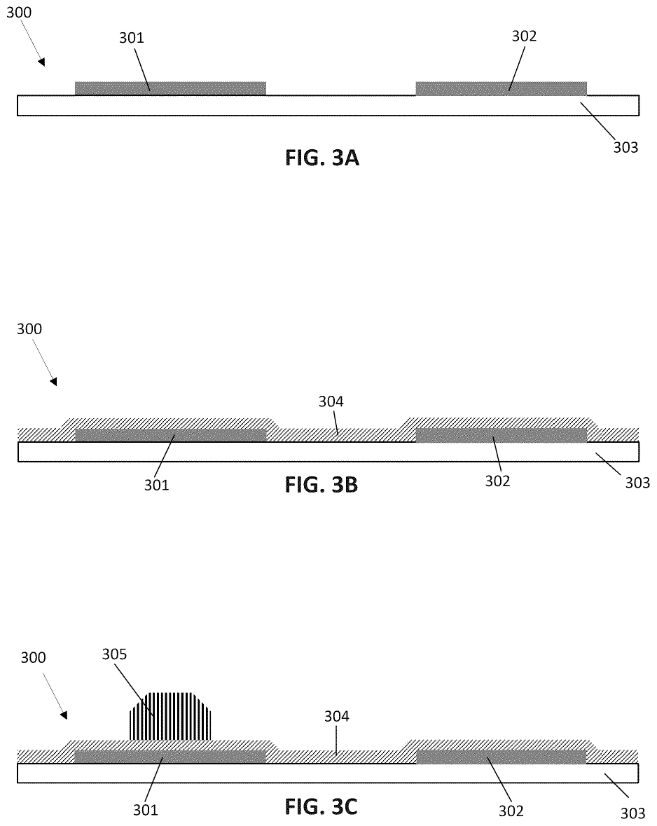

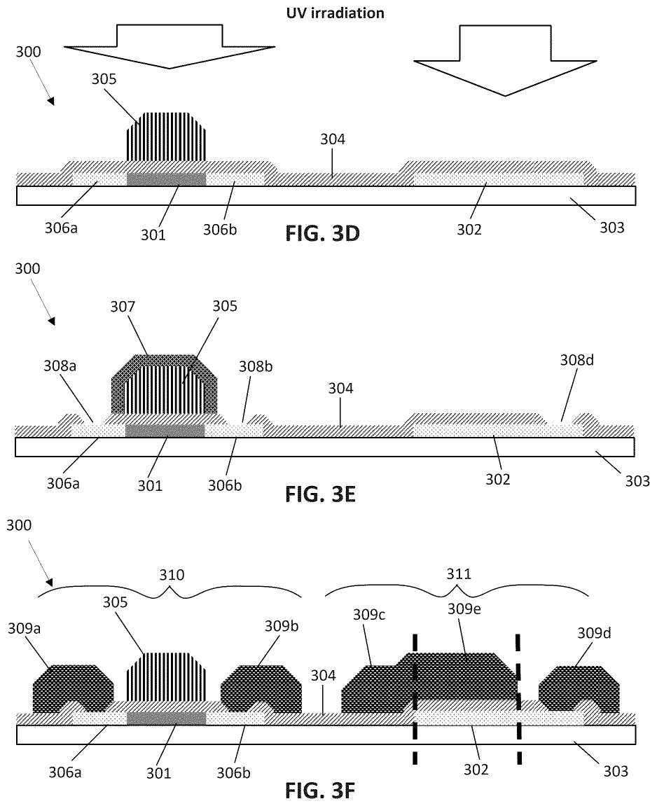

FIGS. 3A to 3F illustrate a method for manufacturing an integrated electronic circuit comprising an LTPS p-type TFT in conjunction with a first type of capacitor;

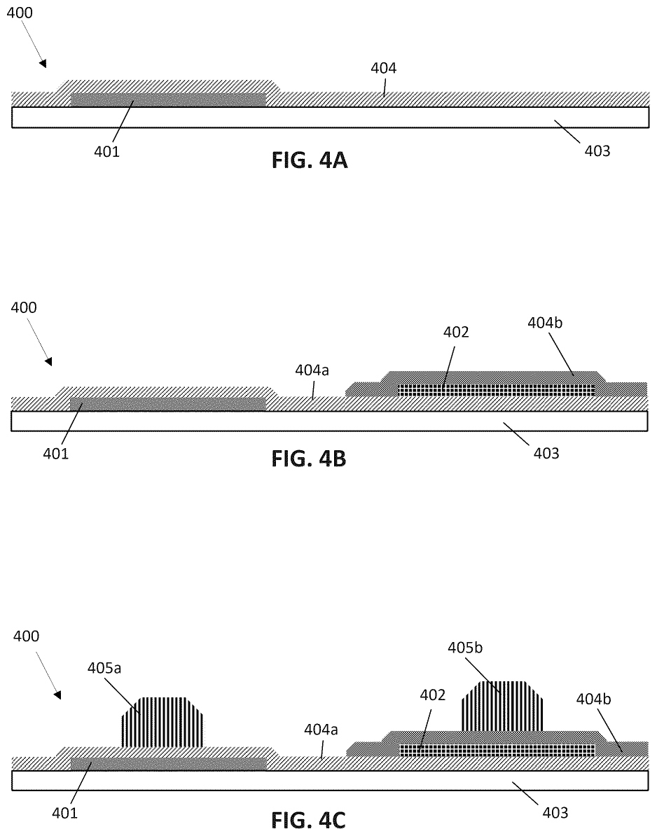

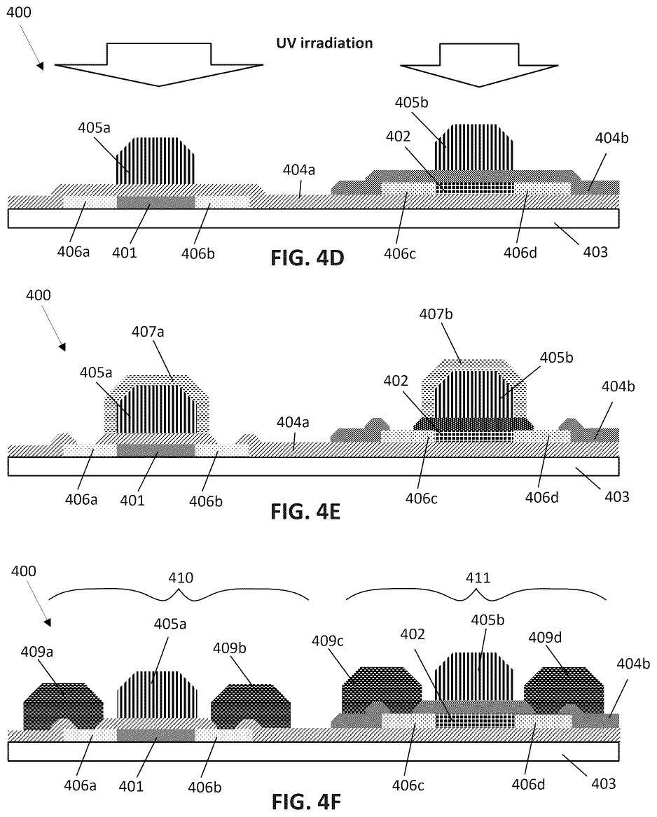

FIGS. 4A to 4F illustrate a method for manufacturing an integrated electronic circuit comprising an LTPS p-type TFT in conjunction with a second type of n-type TFT; and

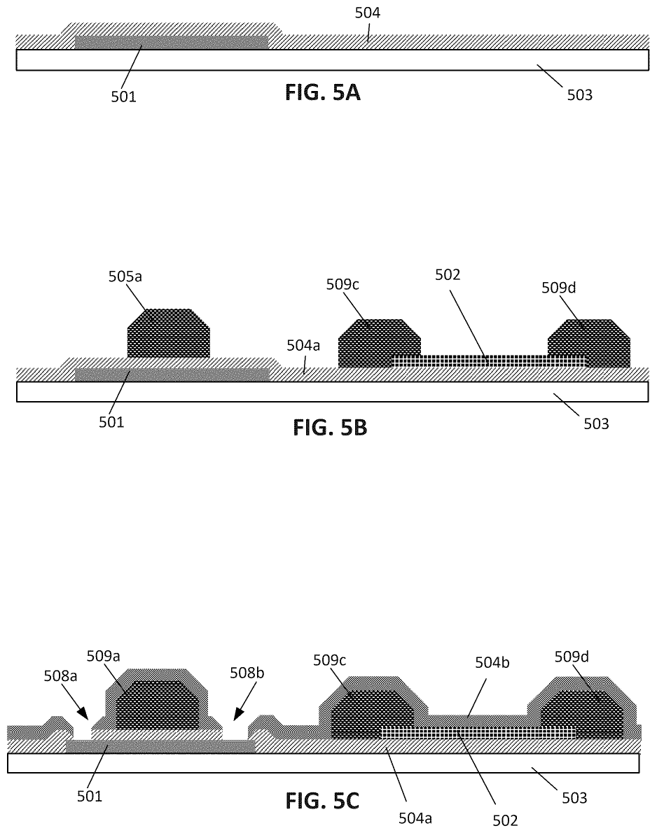

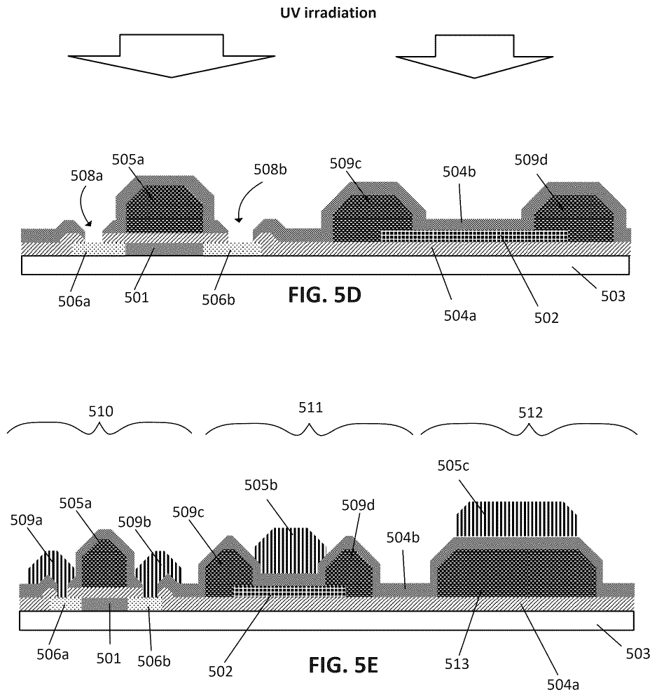

FIGS. 5A to 5E illustrate a method for manufacturing an integrated electronic circuit comprising an LTPS p-type TFT in conjunction with a second type of capacitor.

### OVERVIEW

FIGS. 1A to 1F, 2A to 2F, 3A to 3F, 4A to 4F, 5A to 5E, illustrate a number of different manufacturing processes which may be used in the fabrication of one or more integrated circuits (ICs). Each of the exemplary manufacturing processes illustrated in the figures relates to the provision of an electronic circuit comprising a p-type (also known as ‘p-channel’) thin film transistor (TFT), having a channel region formed using low temperature polysilicon (LTPS), in conjunction with at least one other electronic component (e.g., a resistor, another TFT, a capacitor, etc.). For simplicity of description, such TFTs are referred to herein as LTPS TFTs.

It will be appreciated that, as those skilled in the art would readily understand, whilst the different processes, and associated electronic component combinations, are illustrated separately for clarity of description, the various processes may be integrated into a single manufacturing process to form a more complex integrated circuit comprising any required combination of one or more p-type TFTs with one or more other electronic components (e.g., one or more resistors of the same or different types, one or more n-type (or ‘n-channel’) TFTs of the same or different types, one or more capacitors of the same or different types, etc.). It will also be appreciated that, as those skilled in the art would readily understand, the various processes may be integrated to provide a plurality of essentially separate integrated circuits (e.g., for providing different complementary functions) as part of a single IC chip.

FIGS. 1A to 1F illustrate a method for manufacturing an integrated electronic circuit comprising an LTPS p-type TFT in conjunction with a resistor. Beneficially, as described in more detail later, the resistor is formed of the same source material (polysilicon) as the channel (and source and drain) regions of the p-type TFT thereby providing for a simple, low cost, manufacturing procedure involving relatively few steps. It will be appreciated that resistors are fundamental electronic circuit components that can be used as building blocks for numerous different electronic circuits serving numerous different functions.

FIGS. 2A to 2F illustrate a method for manufacturing an integrated electronic circuit comprising the LTPS p-type TFT in conjunction with a first type of n-type TFT. Beneficially, as described in more detail later, the first type of n-type TFT is a semiconducting oxide based TFT (formed using indium gallium zinc oxide (IGZO) in the illustrated example). Moreover, and somewhat counter-intuitively, the LTPS is deliberately formed to have a carrier mobility that is lower than is currently possible for LTPS (and is therefore relatively closer to that of the channel region of the n-type TFT) thereby allowing complementary p-type and n-type TFTs with similar characteristics to be fabricated (e.g., for the purposes of providing CMOS based electronic circuits). It will be appreciated that there are numerous different possible electronic circuits that would benefit from the ability to fabricate such complementary p-type and n-type TFTs (i.e., CMOS) in this way.

FIGS. 3A to 3F illustrate a method for manufacturing an integrated electronic circuit comprising the LTPS p-type TFT in conjunction with a first type of capacitor. Beneficially, as described in more detail later, the first type of capacitor is formed as a semiconductor-insulator-metal capacitor (SIMCap) where the semiconductor forms one of the capacitor's contact ‘plates’ and is fabricated of the same source material (LTPS polysilicon) as the channel (and source and drain) regions of the p-type TFT, thereby providing for a simple, low cost, manufacturing procedure involving relatively few steps. It will be appreciated that capacitors are fundamental electronic circuit components that can be used as building blocks for numerous different electronic circuits serving numerous different functions.

FIGS. 4A to 4F illustrate a method for manufacturing an integrated electronic circuit comprising the LTPS p-type TFT in conjunction with a second type of n-type TFT. Beneficially, as described in more detail later, the second type of n-type TFT is another semiconducting oxide based TFT (formed using indium gallium zinc oxide IGZO in the illustrated example). However, unlike the first type of n-type TFT, the second type of TFT does not share the same gate dielectric as the LTPS p-type TFT. This allows for independent control of the respective gate dielectric thicknesses (and/or possibly the use of different material with different dielectric constants) for each TFT and hence allows at least some independent control of the electrical characteristics associated with the gate dielectric such as turn-on voltage and/or capacitances associated with the gate dielectric), e.g., for the purposes of balancing the characteristics of the different transistor types. Moreover as with the first type of complementary TFT, and somewhat counter-intuitively, the LTPS is deliberately formed to have a carrier mobility that is lower than is currently possible for LTPS (and is therefore relatively closer to that of the channel region of the n-type TFT) thereby allowing complementary p-type and n-type TFTs with similar characteristics to be fabricated (e.g., for the purposes of providing CMOS based electronic circuits). It will be appreciated that there are numerous different possible electronic circuits that would benefit from the ability to fabricate such complementary p-type and n-type TFTs (i.e., CMOS) in this way.

FIGS. 5A to 5E illustrate a method for manufacturing an integrated electronic circuit comprising the LTPS p-type TFT in conjunction with a third type of n-type TFT, and a second type of capacitor. Beneficially, as described in more detail later, the third type of n-type TFT is another semiconducting oxide based TFT (formed using indium gallium zinc oxide IGZO in the illustrated example). Like the second type of n-type TFT, the third type of TFT does not share the same gate dielectric as the LTPS p-type TFT thereby allowing for independent control of the respective gate dielectric thicknesses and/or material. Moreover as with the first type of complementary TFT, and somewhat counter-intuitively, the LTPS is deliberately formed to have a carrier mobility that is lower than is currently possible for LTPS (and is therefore relatively closer to that of the channel region of the n-type TFT) thereby allowing complementary p-type and n-type TFTs with similar characteristics to be fabricated (e.g., for the purposes of providing CMOS based electronic circuits). It will be appreciated that there are numerous different possible electronic circuits that would benefit from the ability to fabricate such complementary p-type and n-type TFTs (i.e., CMOS) in this way.

Beneficially, the second type of capacitor of this example is formed as a metal-insulator-metal capacitor (MIMCap) where the insulator of the capacitor also forms the gate dielectric of the third type of n-type TFT. It will be appreciated that capacitors are fundamental electronic circuit components that can be used as building blocks for numerous different electronic circuits serving numerous different functions.

In summary, therefore, the various examples described herein illustrate how a simplified low temperature polysilicon (LTPS) process may be used to form p-type TFTs in conjunction with a number of different devices. The process may be combined with a process for forming semiconducting oxide based n-type TFTs (e.g., formed from IGZO or the like) and thus beneficially supports the fabrication of complementary devices arranged to form CMOS based circuits, such as CMOS inverters (and other circuits that use complementary devices) on flexible substrates as part of a flexible IC (e.g., a FlexIC or the like). It will be nevertheless appreciated that the processes described are not limited to flexible substrates and may be used to form ICs comprising CMOS based or other circuitry on rigid substrates such as glass, or any other rigid substrate. It will also be appreciated that the technology disclosed has potentially wide ranging application, for example in displays, product packaging, medical devices, etc.

In particular, by fabricating the p-type TFTs from what might be considered a ‘low performance’ LTPS layer that has carrier mobilities relatively close to those exhibited by the semiconducting oxide which any n-type TFT will use (e.g., within an order of magnitude or so of one another), the technology ameliorates some of the issues normally associated with LTPS. Desired ‘low’ carrier mobilities could, for example, be achieved by annealing with a blue LED or blue laser diode, and/or by using plasma-based doping. At the same time, the relatively lower mobility allows formation of p-type LTPS TFTs, and n-type semiconducting oxide based TFTs of similar sizes (e.g., within an order of magnitude or so of one another) with similar performance characteristics. Thus ICs formed using the disclosed technology can take advantage of the low off-current offered by n-type semiconducting oxide based TFTs whilst still retaining the ability to produce CMOS based circuits (and other circuits that use complementary devices).

The charge mobility (or “charge carrier mobility” or “mobility”) of the LTPS used for the p-type TFTs may, for example, be in the range of between approximately 1 to 200 cm²/V·s inclusive (e.g., within a 10% tolerance), depending on the charge mobility of the semiconducting oxide used for the n-type TFTs, but is preferably closer to that of the channel region of the n-type TFTs (say approximately 1 to 40 cm²/V·s inclusive—e.g., within a 10% tolerance). The charge mobility of the LTPS may, for example, have charge mobility of from 1 to 40 cm²/V·s, such as, for example, 1.5 to 39 cm²/V·s, 2 to 38 cm²/V·s, 2.5 to 37 cm²/V·s, 3 to 36 cm²/V·s, 3.5 to 35.5 cm²/V·s, 4 to 35 cm²/V·s, 4.5 to 35 cm²/V·s, 5 to 34 cm²/V·s, 5.5 to 33 cm²/V·s, 6 to 32 cm²/V·s, 6.5 to 31 cm²/V·s, 7 to 30 cm²/V·s, 7.5 to 29 cm²/V·s, 8 to 28 cm²/V·s, 8.5 to 27 cm²/V·s, 9 to 26 cm²/V·s, 9.5 to 25 cm²/V·s, 10 to 24 cm²/V·s, or 11 to 23 cm²/V·s.

The charge mobility of the LTPS may, for example, be a factor of between 1 and 20 times that of the semiconducting oxide used for the n-type TFTs. For example, the charge mobility of the LTPS may be a factor of between 2 and 19, or between 3 and 18, or between 4 and 17, or between 5 and 16, or between 6 and 15, or between 7 and 14, or between 8 and 13, or between 9 and 12, or between 10 and 11 times that of the semiconducting oxide used for the n-type TFTs. The charge mobility of the LTPS may be a factor of between 1 and 15 times that of the semiconducting oxide used for the n-type TFTs. For example, the charge mobility of the LTPS may be a factor of between 2 and 14, or between 3 and 13, or between 4 and 12, or between 5 and 11, or between 6 and 10, or between 7 and 9 times that of the semiconducting oxide used for the n-type TFTs. The charge mobility of the LTPS may be a factor of between 1 and 10 times that of the semiconducting oxide used for the n-type TFTs. For example, the charge mobility of the LTPS may be a factor of between 2 and 9, or between 3 and 8, or between 4 and 7, or between 5 and 6 times that of the semiconducting oxide used for the n-type TFTs. The charge mobility of the LTPS may be a factor of between 1 and 5 times that of the semiconducting oxide used for the n-type TFTs. For example, the charge mobility of the LTPS may be a factor of between 1.5 and 4.5, or between 2 and 4, or between 2.5 and 3.5 times that of the semiconducting oxide use for the n-type TFTs.

As will be described in more detail, it has been established that using the techniques introduced, above and described in more detail below, to integrate a relatively small semiconducting oxide (e.g., IGZO) based n-type TFT (e.g., where the n-type TFT has a channel length of between 0.1 μm and 5 μm, such as between 0.2 μm and 1 μm, or between 0.3 μm and 0.6 μm) with a larger LTPS based p-type TFT can help to:
offset the lower mobility of the semiconductor oxide (typically ~10 cm²/V·s compared with >50 cm²/V·s for LTPS);
reduce and/or offset the different effects of parasitic capacitance; and/or
offset differences in gate insulator capacitance.

In other words, it can be seen that CMOS capability with reasonably well balanced p-type and n-type devices can be achieved, by leveraging the ability to fabricate semiconducting oxide (IGZO) based devices at smaller dimensions than is typically achievable for LTPS (due to limitations in known LTPS fabrication techniques which are hindered by grain boundary limitations of the LTPS channels produced, which pose a challenge to fabricating TFT channel lengths of <1 μm, e.g., when using the highest mobility LTPS generally preferred for enhancing device performance).

### LTPS P-type TFT and LTPS Resistor

The method for manufacturing an integrated electronic circuit comprising an LTPS p-type TFT in conjunction with a resistor, introduced above, will now be described, by way of example only, with reference to FIGS. 1A to 1F which show an IC being formed generally at 100.

Referring to FIG. 1A, initially a substrate is prepared. The substrate 103 may be formed of any suitable rigid or flexible material, but will typically comprise polyimide (PI) or glass. The substrate may be any appropriate thickness, for example 700 μm of glass or between 1 to 500 μm of polyimide.

A barrier layer (or ‘buffer layer’ or ‘under-layer’) may be deposited on the substrate 103 before formation of the electronic components commences. If a barrier layer is provided on the substrate (e.g., between the component devices and the substrate) it may comprise, for example, a thin (e.g., ~200 nm or the like) silicon nitride (SiNₓ) layer, possibly with a silicon dioxide (SiO₂) interface layer (e.g., ~50 nm or the like). Nevertheless, this is only one example, the barrier layer may comprise other materials as described later.

A blanket layer of amorphous silicon of an appropriate thickness is deposited on the substrate 103 (or on the barrier layer) using any suitable deposition technique (e.g., physical vapour deposition (e.g. sputter, pulsed laser, evaporation), chemical vapour deposition (e.g. plasma-enhanced chemical vapour deposition (PECVD)); coating (e.g. spin), and/or any other suitable processes). The amorphous silicon layer may, for example, have a thickness below 200 nm (e.g., 20 to 30 nm, 50 nm or 100 nm).

The amorphous silicon is subsequently crystallised to form LTPS having the required characteristics—e.g., as mentioned above the relatively low charge carrier mobility similar to that of IGZO (which is typically of the order of ~10 cm²/V·s), for example in the range of 1 to 40 cm²/V·s inclusive mentioned above. Crystallisation is achieved using an appropriate ‘low-temperature’ technique that is compatible with the requirements of LTPS and the substrate being used. This may involve, for example, annealing with a laser (e.g., an excimer (gas) laser or blue solid state (diode) laser) or blue light-emitting diode (LED) or lamp or possibly even using ‘low-temperature’ thermal annealing where appropriate. To help achieve the desired mobility, the deposition and/or crystallisation conditions may be tuned. Moreover, the amorphous silicon/LTPS may be doped appropriately.

The LTPS layer is then patterned (e.g., using an appropriate mask and photolithographic techniques) to form a plurality of LTPS islands 101, 102. Each LTPS island 101, 102 may have the same or different dimensions. The first LTPS island 101 has dimensions (length/width/cross-sectional area) defined to allow the fabrication of a p-type TFT with a channel region/channel having the required dimensions (e.g., a channel length in the region of 1 to 20 μm). The second LTPS island 102 has dimensions (length/width/cross-sectional area) defined to allow the fabrication of a resistor of the required resistance.

As seen in FIG. 1B, a blanket insulating/dielectric layer 104 is subsequently deposited that covers the first and second LTPS islands 101, and 102, and the substrate 103. It is part of this insulating/dielectric layer 104 that will ultimately form the gate dielectric of the p-type TFT. This insulating/dielectric layer 104 may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The insulating/dielectric layer 104 may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different.

Turning to FIG. 1C, a gate electrode 105 is formed over the first LTPS island 101, on a portion of the insulating/dielectric layer 104 that covers LTPS island 101. The gate electrode 105 is located at a position that is vertically aligned (in the orientation shown in FIG. 1C) with the part of the first LTPS island 101 that will ultimately form the channel region of the finished p-type TFT when completed. Similarly, the gate electrode 105 has dimensions (length/width/cross-sectional area) that corresponds to the desired dimensions of the channel region of the finished p-type TFT when completed. Nevertheless, it will be appreciated that whilst the gate-channel region alignment and corresponding dimensions allows the gate to be used, in effect, as a mask for defining the channel region as part of a self-aligned process as described herein, in an alternative (not self-aligned) route, the gate electrode may be formed later and, instead, a photoresist cap could be used, instead of the gate material, to mask the channel region.

The gate electrode 105 may, for example, be formed by first depositing a suitable layer of conductive material, using any appropriate deposition techniques (e.g., by evaporation or sputtering), to an appropriate thickness. The conductive material may, for example, comprise a metal (such as Molybdenum (Mo) or the like) layer having a thickness of 1200 Å or the like. Nevertheless, this is only one example, the conductive layer may comprise other materials as described later. The conductive material of the gate electrode is then patterned (e.g., using an appropriate mask and photolithographic techniques) to form the gate electrode 105.

As illustrated in FIG. 1D, the structure is then irradiated with electro-magnetic radiation (e.g., with ultraviolet (UV) light). The electro-magnetic radiation converts any unshielded semiconducting LTPS to a higher conductivity (ohmic—e.g., ~1Ω/□) form. This conversion process may also be contributed to by the release of dopants from surrounding materials. The electro-magnetic radiation is not stopped by the material of the dielectric layer 104 but is stopped by the material of the gate electrode 105. Accordingly, the region of the first (p-type TFT) LTPS island 101 directly below the gate electrode 105 is shielded from the electro-magnetic radiation by the material of gate electrode 105 and remains semiconducting. Contrastingly, the regions 106a and 106b of the first (p-type TFT) LTPS island 101 that are not directly below the gate electrode 105 are not shielded from the electro-magnetic radiation and are therefore converted. These conducting regions 106a and 106b ultimately become the source and drain regions of the p-type TFT when completed. Similarly, the second (resistor) LTPS island 102 is not shielded from the electro-magnetic radiation, is therefore converted, and can hence form a resistor having a resistance determined, at least in part, by the dimensions of the second (resistor) LTPS island 102.

As seen in FIG. 1E, following the irradiation, the insulating/dielectric layer 104 is patterned and etched to form vias 108a, 108b, 108c, and 108d through the insulating/dielectric layer 104 to provide for electrical connection: to the source and drain regions 106a and 106b of the p-type TFT when completed (vias 108a and 108b); and to either end of the second (resistor) LTPS island 102 and hence the LTPS resistor when completed (vias 108c and 108d).

An etch-stop layer 107 is formed (e.g., by deposition and patterning of an appropriate material) over the gate electrode 105 to provide protection during a subsequent metal etch. It will be appreciated that in the alternative (not self-aligned) route, the gate electrode may not have been formed at this stage and so the etch stop is not needed (although the mask used during the irradiation will of course need to be removed).

Referring to FIG. 1F, a further layer of conducting material is deposited (e.g., by sputtering). The conductive material may, for example, comprise a metal (such as Molybdenum (Mo) or the like) layer having a thickness of 150 nm or the like. Nevertheless, this is only one example, the conductive layer may comprise other materials as described later. The conductive material is then patterned (e.g., using an appropriate mask and photolithographic techniques) to form: source and drain electrodes 109a and 109b for respectively connecting to source and drain regions 106a and 106b of the p-type TFT via vias 108a and 108b; and resistor contacts/electrodes for connecting to either end of the second (resistor) LTPS island 102 (and hence the LTPS resistor when completed) via vias 108c and 108d. The etch-stop layer 107 may then be removed. It will be appreciated that in the alternative (not self-aligned) route, the gate electrode may be formed at this stage.

It will be appreciated that at this step other metal features (tracking, capacitor plates, etc) may be formed in the same layer. Moreover, this step may (optionally) be used for forming the anode of a metal-semiconductor (Schottky) diode if needed.

Accordingly, as seen in FIG. 1F, the integrated electronic circuit comprises an LTPS p-type TFT 110 in conjunction with a resistor 111.

### Complementary LTPS P-Type TFT and Semiconducting Oxide Based N-Type TFT

The method for manufacturing an integrated electronic circuit comprising an LTPS p-type TFT in conjunction with a semiconducting oxide based n-type TFT, introduced above, will now be described, by way of example only, with reference to FIGS. 2A to 2F which show an IC being formed generally at 200.

Referring to FIG. 2A, initially a substrate 203 is prepared. The substrate 203 may be formed of any suitable rigid or flexible material but will typically comprise, polyimide (PI) or glass. The substrate 203 may be any appropriate thickness, for example 700 μm of glass or 1-500 μm of polyimide.

A barrier layer (or ‘buffer layer’ or ‘under-layer’) may be deposited on the substrate 203 before formation of the electronic components commences. If a barrier layer is provided on the substrate (e.g., between the component devices and the substrate) it may comprise, for example, a thin (e.g., ~200 nm or the like) silicon nitride (SiNₓ) layer, possibly with a silicon dioxide (SiO₂) interface layer (e.g., ~50 nm or the like). Nevertheless, this is only one example, the barrier layer may comprise other materials as described later.

A blanket layer of amorphous silicon of an appropriate thickness is deposited on the substrate 203 (or on the barrier layer) using any suitable deposition technique (e.g., physical vapour deposition (e.g. sputter, pulsed laser, evaporation), chemical vapour deposition (e.g. plasma-enhanced chemical vapour deposition (PECVD)); coating (e.g. spin), and/or any other suitable processes). The amorphous silicon layer may, for example, have a thickness below 200 nm (e.g., 20 to 30 nm, 50 nm or 100 nm).

The amorphous silicon is subsequently crystallised to form LTPS having the required characteristics—e.g., as mentioned above the relatively low charge carrier mobility similar to that of IGZO (which is typically of the order of ~10 cm²/V·s), for example in the range 1 to 40 cm²/V·s inclusive mentioned above. Crystallisation is achieved using an appropriate ‘low-temperature’ technique that is compatible with the requirements of LTPS and the substrate being used. This may involve, for example, annealing with a laser (e.g., an excimer (gas) laser or blue solid state (diode) laser) or blue light-emitting diode (LED) or lamp or possibly even using ‘low-temperature’ thermal annealing where appropriate. To help achieve the desired mobility, the deposition and/or crystallisation conditions may be tuned. Moreover, the amorphous silicon/LTPS may be doped appropriately.

The LTPS layer is then patterned (e.g., using an appropriate mask and photolithographic techniques) to form one or more LTPS islands 201. The LTPS island(s) 201 include at least one LTPS island 201 that has dimensions (length/width/cross-sectional area) defined to allow the fabrication of a p-type TFT with a channel region/channel having the required dimensions (e.g., a channel length in the region of 1 to 20 μm).

A layer of semiconducting oxide (e.g., IGZO) suitable for formation of the channel region of the semiconducting oxide based n-type TFT is then deposited (e.g., using an appropriate deposition technique such as reactive sputtering or the like) to an appropriate thickness (e.g., ~20 nm or the like) and patterned (e.g., using an appropriate mask and photolithographic techniques) to form one or more semiconducting oxide islands 202 suitable for forming the channel region of the n-type TFT. At least one semiconducting oxide island 202 has dimensions (length/width/cross-sectional area) defined to allow the fabrication of an n-type TFT with a channel region/channel having the required dimensions (e.g., a channel length of between 0.1 μm and 5 μm, such as between 0.2 μm and 1 μm, or between 0.3 μm and 0.6 μm). It will be appreciated that whilst the LTPS island(s) 201 and semiconducting oxide island(s) 202 may have the same dimensions, the dimensions of LTPS island(s) 201 may be different to those of semiconducting oxide island(s) 202. Specifically, the relative dimensions of the islands 201, 202 may be specifically designed to produce a p-type and an n-type TFT that have similar performance characteristics taking into account differences between the mobility of the LTPS and of the semiconducting oxide (e.g., IGZO).

It will be appreciated that, whilst not shown one or more LTPS based resistors may be fabricated in parallel (e.g., from one or more additional LTPS islands) as described previously with respect to FIGS. 1A to 1F. Similarly, one or more semiconducting oxide based resistors may be fabricated in parallel broadly in the manner described for the LTPS based resistors with respect to FIGS. 1A to 1F but starting from one or more semiconducting oxide islands as opposed to LTPS islands.

As seen in FIG. 2B, a blanket insulating/dielectric layer 204 is subsequently deposited that covers the LTPS and semiconducting oxide islands 201, and 202, and the substrate 203. Part of this insulating/dielectric layer 204 will ultimately form the gate dielectric of the p-type TFT and another part of this insulating/dielectric layer 204 will ultimately form the gate dielectric of the n-type TFT. This insulating/dielectric layer 204 may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The insulating/dielectric layer 204 may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different.

Turning to FIG. 2C, a respective gate electrode 205a and 205b is formed over each of the LTPS island 201 for the p-type TFT, and the semiconducting oxide island 202 for the n-type TFT, on a respective portion of the insulating/dielectric layer 204 that covers each island. Each gate electrode 205a, 205b is respectively located at a position that is vertically aligned (in the orientation shown in FIG. 2C) with the part of the corresponding island 201, 202 that will ultimately form the channel region of the corresponding finished p-type TFT or n-type TFT when completed. Similarly, each gate electrode 205a, 205b has dimensions (length/width/cross-sectional area) that corresponds to the desired dimensions of the channel region of the corresponding finished p-type TFT or n-type TFT when completed. Nevertheless, it will be appreciated that whilst the gate-channel region alignment and corresponding dimensions allows each gate to be used, in effect, as a mask for defining the corresponding channel region as part of a self-aligned process as described herein, in an alternative (not self-aligned) route, the gate electrodes may be formed later and, instead, a photoresist cap could be used, instead of the gate material, to mask the channel region.

The gate electrodes 205a, 205b may, for example, be formed by first depositing a suitable layer of conductive material, using any appropriate deposition techniques (e.g., by evaporation or sputtering), to an appropriate thickness. The conductive material may, for example, comprise a metal (such as Molybdenum (Mo) or the like) layer having a thickness of 1200 Å or the like. Nevertheless, this is only one example, the conductive layer may comprise other materials as described later. The conductive material of the gate electrodes is then patterned (e.g., using an appropriate mask and photolithographic techniques) to form the gate electrodes.

As illustrated in FIG. 2D, the structure is then irradiated with electro-magnetic radiation (e.g., with ultraviolet (UV) light). The electro-magnetic radiation converts any unshielded semiconducting LTPS and any unshielded semiconducting oxide to a higher conductivity (ohmic—e.g., ~1Ω/□) form. This conversion process may also be contributed to by the release of dopants from surrounding materials. The electro-magnetic radiation is not stopped by the material of the dielectric layer 204 but is stopped by the material of the gate electrodes 205a and 205b. Accordingly, the region of the LTPS island 201 directly below the gate electrode 205a for the p-type TFT is shielded from the electro-magnetic radiation by the material of that gate electrode 205a and remains semiconducting. Similarly, the region of the semiconducting oxide island 202 directly below the gate electrode 205b for the n-type TFT is shielded from the electro-magnetic radiation by the material of that gate electrode 205b and remains semiconducting.

Contrastingly, the regions 206a and 206b of the LTPS island 201 for the p-type TFT that are not directly below the corresponding gate electrode 205a are not shielded from the electro-magnetic radiation and are therefore converted. These conducting regions 206a and 206b ultimately become the source and drain regions of the p-type TFT when completed. Similarly, the regions 206c and 206d of the semiconducting oxide island 202 for the n-type TFT that are not directly below the corresponding gate electrode 205b are not shielded from the electro-magnetic radiation and are therefore converted. These conducting regions 206c and 206d ultimately become the source and drain regions of the n-type TFT when completed.

As seen in FIG. 2E, following the irradiation, the insulating/dielectric layer 204 is patterned and etched to form vias 208a, 208b, 208c, and 208d through the insulating/dielectric layer 204 to provide for electrical connection: to the source and drain regions 206a and 206b of the p-type TFT when completed (vias 208a and 208b); and to the source and drain regions 206c and 206d of the n-type TFT when completed (vias 208c and 208d).

A respective etch-stop layer portion 207a, 207b is formed (e.g., by deposition and patterning of an appropriate material) over each of the gate electrodes 205a, 205b to provide protection during a subsequent metal etch. It will be appreciated that in the alternative (not self-aligned) route, the gate electrode may not have been formed at this stage and so the etch stops are not needed (although the mask used during the irradiation will of course need to be removed).

Referring to FIG. 2F, a further layer of conducting material is deposited (e.g., by sputtering). The conductive material may, for example, comprise a metal (such as Molybdenum (Mo) or the like) layer having a thickness of 150 nm or the like. Nevertheless, this is only one example, the conductive layer may comprise other materials as described later. The conductive material is then patterned (e.g., using an appropriate mask and photolithographic techniques) to form: source and drain electrodes 209a and 209b for respectively connecting to source and drain regions 206a and 206b of the p-type TFT via vias 208a and 208b; and source and drain electrodes 209c and 209d for respectively connecting to source and drain regions 206c and 206d of the n-type TFT via vias 208c and 208d. The etch-stop layer portions 207a, 207b may then be removed. It will be appreciated that in the alternative (not self-aligned) route, the gate electrodes may be formed at this stage.

It will be appreciated that at this step other metal features (tracking, capacitor plates, etc) may be formed in the same layer. Moreover, this step may (optionally) be used for forming the anode of a metal-semiconductor (Schottky) diode if needed.

Accordingly, as seen in FIG. 2F, the integrated electronic circuit comprises an LTPS p-type TFT 210 in conjunction with a semiconductor oxide based n-type TFT 211.

### LTPS P-Type TFT and SIMCap

The method for manufacturing an integrated electronic circuit comprising an LTPS p-type TFT in conjunction with a first type of capacitor, introduced above, will now be described, by way of example only, with reference to FIGS. 3A to 3F which show an IC being formed generally at 300.

Referring to FIG. 3A, initially a substrate is prepared. The substrate 303 may be formed of any suitable rigid or flexible material but will typically comprise, polyimide (PI) or glass. The substrate may be any appropriate thickness, for example 700 μm of glass or 1-500 μm of polyimide.

A barrier layer (or ‘buffer layer’ or ‘under-layer’) may be deposited on the substrate 303 before formation of the electronic components commences. If a barrier layer is provided on the substrate (e.g., between the component devices and the substrate) it may comprise, for example, a thin (e.g., ~200 nm or the like) silicon nitride (SiNₓ) layer, possibly with a silicon dioxide (SiO₂) interface layer (e.g., ~50 nm or the like). Nevertheless, this is only one example, the barrier layer may comprise other materials as described later.

A blanket layer of amorphous silicon of an appropriate thickness is deposited on the substrate 303 (or on the barrier layer) using any suitable deposition technique (e.g., physical vapour deposition (e.g. sputter, pulsed laser, evaporation), chemical vapour deposition (e.g. plasma-enhanced chemical vapour deposition (PECVD)); coating (e.g. spin), and/or any other suitable processes). The amorphous silicon layer may, for example, have a thickness below 200 nm (e.g., 20 to 30 nm, 50 nm or 100 nm).

The amorphous silicon is subsequently crystallised to form LTPS having the required characteristics—e.g., as mentioned above the relatively low charge carrier mobility similar to that of IGZO (which is typically of the order of ~10 cm²/V·s), for example in the range 1 to 40 cm²/V·s inclusive mentioned above. Crystallisation is achieved using an appropriate ‘low-temperature’ technique that is compatible with the requirements of LTPS and the substrate being used. This may involve, for example, annealing with a laser (e.g., an excimer (gas) laser or blue solid state (diode) laser) or blue light-emitting diode (LED) or lamp or possibly even using ‘low-temperature’ thermal annealing where appropriate. To help achieve the desired mobility, the deposition and/or crystallisation conditions may be tuned. Moreover, the amorphous silicon/LTPS may be doped appropriately.

The LTPS layer is then patterned (e.g., using an appropriate mask and photolithographic techniques) to form a plurality of LTPS islands 301, 302. Each LTPS island 301, 302 may have the same or different dimensions. The first LTPS island 301 has dimensions (length/width/cross-sectional area) defined to allow the fabrication of a p-type TFT with a channel region/channel having the required dimensions (e.g., a channel length in the region of 1 to 20 μm). The second LTPS island 302 has dimensions (length/width/cross-sectional area) defined to allow the second LTPS island 302 to form one plate of a capacitor having the required capacitance.

As seen in FIG. 3B, a blanket insulating/dielectric layer 304 is subsequently deposited that covers the first and second LTPS islands 301, and 302, and the substrate 303. It is part of this insulating/dielectric layer 304 that will ultimately form the gate dielectric of the p-type TFT. This insulating/dielectric layer 304 may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The insulating/dielectric layer 304 may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different.

Turning to FIG. 3C, a gate electrode 305 is formed over the first LTPS island 301, on a portion of the insulating/dielectric layer 304 that covers that LTPS island 301. The gate electrode 305 is located at a position that is vertically aligned (in the orientation shown in FIG. 3C) with the part of the first LTPS island 301 that will ultimately form the channel region of the finished p-type TFT when completed. Similarly, the gate electrode 305 has dimensions (length/width/cross-sectional area) that corresponds to the desired dimensions of the channel region of the finished p-type TFT when completed. Nevertheless, it will be appreciated that whilst the gate-channel region alignment and corresponding dimensions allows the gate to be used, in effect, as a mask for defining the channel region as part of a self-aligned process as described herein in an alternative (not self-aligned) route, the gate electrode may be formed later and, instead, a photoresist cap could be used, instead of the gate material, to mask the channel region.

The gate electrode 305 may, for example, be formed by first depositing a suitable layer of conductive material, using any appropriate deposition techniques (e.g., by evaporation or sputtering), to an appropriate thickness. The conductive material may, for example, comprise a metal (such as Molybdenum (Mo) or the like) layer having a thickness of 1200 Å or the like. Nevertheless, this is only one example, the conductive layer may comprise other materials as described later. The conductive material of the gate electrode is then patterned (e.g., using an appropriate mask and photolithographic techniques) to form the gate electrode.

As illustrated in FIG. 3D, the structure is then irradiated with electro-magnetic radiation (e.g., with ultraviolet (UV) light). The electro-magnetic radiation converts any unshielded semiconducting LTPS to a higher conductivity (ohmic—e.g., ~1Ω/□) form. This conversion process may also be contributed to by the release of dopants from surrounding materials. The electro-magnetic radiation is not stopped by the material of the dielectric layer 304 but is stopped by the material of the gate electrode 305. Accordingly, the region of the first (p-type TFT) LTPS island 301 directly below the gate electrode 305 is shielded from the electro-magnetic radiation by the material of gate electrode 305 and remains semiconducting. Contrastingly, the regions 306a and 306b of the first (p-type TFT) LTPS island 301 that are not directly below the gate electrode 305 are not shielded from the electro-magnetic radiation and are therefore converted. These conducting regions 306a and 306b ultimately become the source and drain regions of the p-type TFT when completed. Similarly, the second (capacitor plate) LTPS island 302 is not shielded from the electro-magnetic radiation, is therefore converted, and can hence form a first (‘lower’) capacitor plate for a capacitor having a capacitance determined, at least in part, by the dimensions of the second (capacitor plate) LTPS island 302.

As seen in FIG. 3E, following the irradiation, the insulating/dielectric layer 304 is patterned and etched to form vias 308a, 308b, and 308d through the insulating/dielectric layer 304 to provide for electrical connection: to the source and drain regions 306a and 306b of the p-type TFT when completed (vias 308a and 308b); and to the second (capacitor plate) LTPS island 302 and hence the first (‘lower’) capacitor plate (via 308d).

An etch-stop layer 307 is formed (e.g., by deposition and patterning of an appropriate material) over the gate electrode 305 to provide protection during a subsequent metal etch. It will be appreciated that in the alternative (not self-aligned) route, the gate electrode may not have been formed at this stage and so the etch stop is not needed (although the mask used during the irradiation will of course need to be removed).

Referring to FIG. 3F, a further layer of conducting material is deposited (e.g., by sputtering). The conductive material may, for example, comprise a metal (such as Molybdenum (Mo) or the like) layer having a thickness of 150 nm or the like. Nevertheless, this is only one example, the conductive layer may comprise other materials as described later. The conductive material is then patterned (e.g., using an appropriate mask and photolithographic techniques) to form: source and drain electrodes 309a and 309b for respectively connecting to source and drain regions 306a and 306b of the p-type TFT via vias 308a and 308b; a first capacitor contact/electrode 309d for connecting to the second (capacitor plate) LTPS island 302 and hence the first (‘lower’) capacitor plate (via the via 308d); a second (‘upper’ or ‘top’) capacitor plate 309e that is vertically aligned (in the orientation shown in FIG. 3F) with the first (‘lower’) capacitor plate formed by the second LTPS island 302; and a second capacitor contact/electrode 309c for connection to the second (‘upper’ or ‘top’) capacitor plate 309e. The etch-stop layer 307 may then be removed. It will be appreciated that in the alternative (not self-aligned) route, the gate electrode may be formed at this stage.

It will be appreciated that at this step other metal features (tracking, capacitor plates, etc) may be formed in the same layer. Moreover, this step may (optionally) be used for forming the anode of a metal-semiconductor (Schottky) diode if needed.

Accordingly, as seen in FIG. 3F, the integrated electronic circuit comprises an LTPS p-type TFT 310 in conjunction with SIMCap type of capacitor 311.

Complementary LTPS P-Type TFT and Semiconducting Oxide Based N-Type TFT with Different Dielectrics

The method for manufacturing an integrated electronic circuit comprising an LTPS p-type TFT in conjunction with a semiconducting oxide based n-type TFT in which the n-type TFT does not share the same gate dielectric as the LTPS p-type TFT, introduced above, will now be described, by way of example only, with reference to FIGS. 4A to 4F which show an IC being formed generally at 400.

Referring to FIG. 4A, initially a substrate 403 is prepared. The substrate 403 may be formed of any suitable rigid or flexible material but will typically comprise, polyimide (PI) or glass. The substrate 403 may be any appropriate thickness, for example 700 μm of glass or 1 to 500 μm of polyimide.

A barrier layer (or ‘buffer layer’ or ‘under-layer’) may be deposited on the substrate 403 before formation of the electronic components commences. If a barrier layer is provided on the substrate (e.g., between the component devices and the substrate) it may comprise, for example, a thin (e.g., ~200 nm or the like) silicon nitride (SiNₓ) layer, possibly with a silicon dioxide (SiO₂) interface layer (e.g., ~50 nm or the like). Nevertheless, this is only one example, the barrier layer may comprise other materials as described later.

A blanket layer of amorphous silicon of an appropriate thickness is deposited on the substrate 403 (or on the barrier layer) using any suitable deposition technique (e.g., physical vapour deposition (e.g. sputter, pulsed laser, evaporation), chemical vapour deposition (e.g. plasma-enhanced chemical vapour deposition (PECVD)); coating (e.g. spin), and/or any other suitable processes). The amorphous silicon layer may, for example, have a thickness below 200 nm (e.g., 20 to 30 nm, 50 nm or 100 nm).

The amorphous silicon is subsequently crystallised to form LTPS having the required characteristics—e.g., as mentioned above the relatively low charge carrier mobility similar to that of IGZO (which is typically of the order of ~10 cm²/V·s), for example in the range 1 to 40 cm²/V·s inclusive mentioned above. Crystallisation is achieved using an appropriate ‘low-temperature’ technique that is compatible with the requirements of LTPS and the substrate being used. This may involve, for example, annealing with a laser (e.g., an excimer (gas) laser or blue solid state (diode) laser) or blue light-emitting diode (LED) or lamp or possibly even using ‘low-temperature’ thermal annealing where appropriate. To help achieve the desired mobility, the deposition and/or crystallisation conditions may be tuned. Moreover, the amorphous silicon/LTPS may be doped appropriately.

The LTPS layer is then patterned (e.g., using an appropriate mask and photolithographic techniques) to form one or more LTPS islands 401. The LTPS island(s) 401 include at least one LTPS island 401 that has dimensions (length/width/cross-sectional area) defined to allow the fabrication of a p-type TFT with a channel region/channel having the required dimensions (e.g., a channel length in the region of 1 to 20 μm). It will be appreciated that, whilst not shown one or more LTPS based resistors may be fabricated in parallel (e.g., from one or more additional LTPS islands) as described previously with respect to FIGS. 1A to 1F. Similarly, one or more SIMCaps may be fabricated in parallel (e.g., from one or more additional LTPS islands) as described previously with respect to FIGS. 2A to 2F.

A first insulating/dielectric layer 404a is subsequently deposited that covers the LTPS island(s) 401 and the substrate 403. It is part of this insulating/dielectric layer 404a that will ultimately form the gate dielectric of the p-type TFT. This insulating/dielectric layer 404a may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The insulating/dielectric layer 404a may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different.

Referring to FIG. 4B, a layer of semiconducting oxide (e.g., IGZO) suitable for formation of the channel region of the semiconducting oxide based n-type TFT is then deposited (e.g., using an appropriate deposition technique such as reactive sputtering or the like) to an appropriate thickness (e.g., ~20 nm or the like) and patterned (e.g., using an appropriate mask and photolithographic techniques) to form one or more semiconducting oxide islands 402 suitable for forming the channel region of the n-type TFT. At least one semiconducting oxide island 402 has dimensions (length/width/cross-sectional area) defined to allow the fabrication of an n-type TFT with a channel region/channel having the required dimensions (e.g., a channel length of between 0.1 μm and 5 μm, such as between 0.2 μm and 1 μm, or between 0.3 μm and 0.6 μm). It will be appreciated that whilst the LTPS island(s) 401 and semiconducting oxide island(s) 402 may have the same dimensions, the dimensions of LTPS island(s) 401 may be different to those of semiconducting oxide island(s) 402. Specifically, the relative dimensions of the islands 401, 402 may be specifically designed to produce a p-type and an n-type TFT that have similar performance characteristics taking into account differences between the mobility of the LTPS and of the semiconducting oxide (e.g., IGZO).

It will be appreciated that one or more semiconducting oxide based resistors may be fabricated in parallel broadly in the manner described for the LTPS based resistors with respect to FIGS. 1A to 1F but starting from one or more additional semiconducting oxide islands formed on the first insulating/dielectric layer 404a as opposed to from LTPS islands formed on the substrate 403.

A second insulating/dielectric layer 404b is subsequently deposited that covers the semiconducting oxide island(s) 402, and the previously formed first insulating/dielectric layer 404. It is part of this second insulating/dielectric layer 404b that will ultimately form the gate dielectric of the n-type TFT. This second insulating/dielectric layer 404b may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The second insulating/dielectric layer 404b may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different. The first insulating/dielectric layer 404a and the second insulating/dielectric layer 404b may have different thicknesses and/or may be formed of different materials to one another.

It will be appreciated that the relationship between the thickness of the part of the second insulating/dielectric layer 404b that will ultimately form the gate dielectric of the n-type TFT, and the thickness of the part of the first insulating/dielectric layer 404a that will ultimately form the gate dielectric of the p-type TFT, may be configured to produce similar parasitic gate dielectric capacitances for the n-type and p-type TFTs (e.g., with the lowest value being within 20% (or more preferably 15% or 10%) of the highest value) even when the respective channel lengths are different. It will, nevertheless, be appreciated that in conjunction with (or instead of) gate dielectric thicknesses this similarity in relationship between the parasitic gate dielectric capacitances may be configured by using different dielectrics with different dielectric constants.

The second insulating/dielectric layer 404b is then patterned and etched (e.g., using an appropriate mask and photolithographic techniques) to expose the first insulating/dielectric layer 404a over the areas in which the p-type TFTs are being formed (i.e., over the LTPS island(s) 401 and surrounding area) and possibly any LTPS island(s) for forming resistors and/or SIMCaps as described previously).

Turning to FIG. 4C, a respective gate electrode 405a and 405b is formed over each of the LTPS island 401 for the p-type TFT, and the semiconducting oxide island 402 for the n-type TFT. Each gate electrode 405a and 405b is formed on a respective portion of the corresponding first insulating/dielectric layer 404a, or second insulating/dielectric layer 404b, that covers each island. Each gate electrode 405a, 405b is respectively located at a position that is vertically aligned (in the orientation shown in FIG. 4C) with the part of the corresponding island 401, 402 that will ultimately form the channel region of the corresponding finished p-type TFT or n-type TFT when completed. Similarly, each gate electrode 405a, 405b has dimensions (length/width/cross-sectional area) that corresponds to the desired dimensions of the channel region of the corresponding finished p-type TFT or n-type TFT when completed. Nevertheless, it will be appreciated that whilst the gate-channel region alignment and corresponding dimensions allows each gate to be used, in effect, as a mask for defining the corresponding channel region as part of a self-aligned process as described herein, in an alternative (not self-aligned) route, the gate electrodes may be formed later and, instead, a photoresist cap could be used, instead of the gate material, to mask the channel region.

The gate electrodes 405a, 405b may, for example, be formed by first depositing a suitable layer of conductive material, using any appropriate deposition techniques (e.g., by evaporation or sputtering), to an appropriate thickness. The conductive material may, for example, comprise a metal (such as Molybdenum (Mo) or the like) layer having a thickness of 1200 Å or the like. Nevertheless, this is only one example, the conductive layer may comprise other materials as described later. The conductive material of the gate electrodes is then patterned (e.g., using an appropriate mask and photolithographic techniques) to form the gate electrodes 405a, 405b.

As illustrated in FIG. 4D, the structure is then irradiated with electro-magnetic radiation (e.g., with ultraviolet (UV) light). The electro-magnetic radiation converts any unshielded semiconducting LTPS and any unshielded semiconducting oxide to a higher conductivity (ohmic—e.g., ~1Ω/□) form. This conversion process may also be contributed to by the release of dopants from surrounding materials. The electro-magnetic radiation is not stopped by the material of the dielectric layer 404a but is stopped by the material of the gate electrodes 405a and 405b. Accordingly, the region of the LTPS island 401 directly below the gate electrode 405a for the p-type TFT is shielded from the electro-magnetic radiation by the material of that gate electrode 405a and remains semiconducting. Similarly, the region of the semiconducting oxide island 402 directly below the gate electrode 405b for the n-type TFT is shielded from the electro-magnetic radiation by the material of that gate electrode 405b and remains semiconducting.

Contrastingly, the regions 406a and 406b of the LTPS island 401 for the p-type TFT that are not directly below the corresponding gate electrode 405a are not shielded from the electro-magnetic radiation and are therefore converted. These conducting regions 406a and 406b ultimately become the source and drain regions of the p-type TFT when completed. Similarly, the regions 406c and 406d of the semiconducting oxide island 402 for the n-type TFT that are not directly below the corresponding gate electrode 405b are not shielded from the electro-magnetic radiation and are therefore converted. These conducting regions 406c and 406d ultimately become the source and drain regions of the n-type TFT when completed.

As seen in FIG. 4E, following the irradiation, the dielectric layers 404a, and 404b are patterned and etched to form vias 408a, 408b through the first insulating/dielectric layer 404a, and to form vias 408c, 408d through the second insulating/dielectric layer 404b to provide for electrical connection: to the source and drain regions 406a and 406b of the p-type TFT when completed (vias 408a and 408b); and to the source and drain regions 406c and 406d of the n-type TFT when completed (vias 408c and 408d).

A respective etch-stop layer portion 407a, 407b is formed (e.g., by deposition and patterning of an appropriate material) over each of the gate electrodes 405a, 405b to provide protection during a subsequent metal etch. It will be appreciated that in the alternative (not self-aligned) route, the gate electrode may not have been formed at this stage and so the etch stops are not needed (although the mask used during the irradiation will of course need to be removed).

Referring to FIG. 4F, a further layer of conducting material is deposited (e.g., by sputtering). The conductive material may, for example, comprise a metal (such as Molybdenum (Mo) or the like) layer having a thickness of 150 nm or the like. Nevertheless, this is only one example, the conductive layer may comprise other materials as described later. The conductive material is then patterned (e.g., using an appropriate mask and photolithographic techniques) to form: source and drain electrodes 409a and 409b for respectively connecting to source and drain regions 406a and 406b of the p-type TFT via vias 408a and 408b; and source and drain electrodes 409c and 409d for respectively connecting to source and drain regions 406c and 406d of the n-type TFT via vias 408c and 408d. The etch-stop layer portions 407a, 407b may then be removed. It will be appreciated that in the alternative (not self-aligned) route, the gate electrodes may be formed at this stage.

It will be appreciated that at this step other metal features (tracking, capacitor plates, etc) may be formed in the same layer. Moreover, this step may (optionally) be used for forming the anode of a metal-semiconductor (Schottky) diode if needed.

Accordingly, as seen in FIG. 4F, the integrated electronic circuit comprises an LTPS p-type TFT 410 in conjunction with a semiconductor oxide based n-type TFT 411 that does not share the same gate dielectric as the p-type TFT 410.

Complementary LTPS P-Type TFT and Semiconducting Oxide Based N-Type TFT with MIMCap

The method for manufacturing an integrated electronic circuit comprising an LTPS p-type TFT in conjunction with a semiconducting oxide based n-type TFT and a MIMCap, introduced above, will now be described, by way of example only, with reference to FIGS. 5A to 5E which show an IC being formed generally at 500.

Referring to FIG. 5A, initially a substrate 503 is prepared. The substrate 503 may be formed of any suitable rigid or flexible material but will typically comprise, polyimide (PI) or glass. The substrate 503 may be any appropriate thickness, for example 700 μm of glass or 1-500 μm of polyimide.

A barrier layer (or ‘buffer layer’ or ‘under-layer’) may be deposited on the substrate 503 before formation of the electronic components commences. If a barrier layer is provided on the substrate (e.g., between the component devices and the substrate) it may comprise, for example, a thin (e.g., ~200 nm or the like) silicon nitride (SiNₓ) layer, possibly with a silicon dioxide (SiO₂) interface layer (e.g., ~50 nm or the like). Nevertheless, this is only one example, the barrier layer may comprise other materials as described later.

A blanket layer of amorphous silicon of an appropriate thickness is deposited on the substrate 503 (or on the barrier layer) using any suitable deposition technique (e.g., physical vapour deposition (e.g. sputter, pulsed laser, evaporation), chemical vapour deposition (e.g. plasma-enhanced chemical vapour deposition (PECVD)); coating (e.g. spin), and/or any other suitable processes). The amorphous silicon layer may, for example, have a thickness below 200 nm (e.g., 20 to 30 nm, 50 nm or 100 nm).

The amorphous silicon is subsequently crystallised to form LTPS having the required characteristics—e.g., as mentioned above the relatively low charge carrier mobility similar to that of IGZO (which is typically of the order of ~10 cm²/V·s), for example in the range 1 to 40 cm²/V·s mentioned above. Crystallisation is achieved using an appropriate ‘low-temperature’ technique that is compatible with the requirements of LTPS and the substrate being used. This may involve, for example, annealing with a laser (e.g., an excimer (gas) laser or blue solid state (diode) laser) or blue light-emitting diode (LED) or lamp or possibly even using ‘low-temperature’ thermal annealing where appropriate. To help achieve the desired mobility, the deposition and/or crystallisation conditions may be tuned. Moreover, the amorphous silicon/LTPS may be doped appropriately.

The LTPS layer is then patterned (e.g., using an appropriate mask and photolithographic techniques) to form one or more LTPS islands 501. The LTPS island(s) 501 include at least one LTPS island 501 that has dimensions (length/width/cross-sectional area) defined to allow the fabrication of a p-type TFT with a channel region/channel having the required dimensions (e.g., a channel length in the region of 1 to 20 μm). It will be appreciated that, whilst not shown one or more LTPS based resistors may be fabricated in parallel (e.g., from one or more additional LTPS islands) as described previously with respect to FIGS. 1A to 1F. Similarly, one or more SIMCaps may be fabricated in parallel (e.g., from one or more additional LTPS islands) as described previously with respect to FIGS. 2A to 2F.

A first insulating/dielectric layer 504a is subsequently deposited that covers the LTPS island(s) 501 and the substrate 503. It is part of this insulating/dielectric layer 504a that will ultimately form the gate dielectric of the p-type TFT. This insulating/dielectric layer 504a may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The insulating/dielectric layer 504a may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different.

Referring to FIG. 5B, a layer of semiconducting oxide (e.g., IGZO) suitable for formation of the channel region of the semiconducting oxide based n-type TFT is then deposited (e.g., using an appropriate deposition technique such as reactive sputtering or the like) to an appropriate thickness (e.g., ~20 nm or the like) and patterned (e.g., using an appropriate mask and photolithographic techniques) to form one or more semiconducting oxide islands 502 suitable for forming the channel region of the n-type TFT. At least one semiconducting oxide island 502 has dimensions (length/width/cross-sectional area) defined to allow the fabrication of an n-type TFT with a channel region/channel having the required dimensions (e.g., a channel length of between 0.1 μm and 5 μm, such as between 0.2 μm and 1 μm, or between 0.3 μm and 0.6 μm). It will be appreciated that whilst the LTPS island(s) 501 and semiconducting oxide island(s) 502 may have the same dimensions, the dimensions of LTPS island(s) 501 may be different to those of semiconducting oxide island(s) 502. Specifically, the relative dimensions of the islands 501, 502 may be specifically designed to produce a p-type and an n-type TFT that have similar performance characteristics taking into account differences between the mobility of the LTPS and of the semiconducting oxide (e.g., IGZO).

It will be appreciated that one or more semiconducting oxide based resistors may be fabricated in parallel broadly in the manner described for the LTPS based resistors with respect to FIGS. 1A to 1F but starting from one or more additional semiconducting oxide islands formed on the first insulating/dielectric layer 504a as opposed to from LTPS islands formed on the substrate 503.

At this stage, as illustrated in FIGS. 5D and 5E, a number of electrodes 505a, 509c, 509d, 513 are also formed (i.e., earlier in the procedure than the process of FIGS. 4A to 4F).

The electrodes 505a, 509c, 509d, 513 include a gate electrode 505a for the p-type TFT that is formed over the LTPS island 501 for the p-type TFT, on a portion of the first insulating/dielectric layer 504a that covers that LTPS island 501. The gate electrode 505a for the p-type TFT is located at a position that is vertically aligned (in the orientation shown in FIG. 5B) with the part of the LTPS island 501 for the p-type TFT that will ultimately form the channel region of the finished p-type TFT when completed. Similarly, the gate electrode 505a for the p-type TFT has dimensions (length/width/cross-sectional area) that corresponds to the desired dimensions of the channel region of the finished p-type TFT when completed.

The electrodes 505a, 509c, 509d, 513 also include source and drain electrodes 509c and 509d for the n-type TFT that are respectively formed at (and overlapping with) either end of the semiconductor oxide island 502 for the n-type TFT, on respective portions of the first insulating/dielectric layer 504a (and, partially, respective ends of the semiconductor oxide island 502).

The electrodes 505a, 509c, 509d, 513 also include a first capacitor electrode 513 (only shown in FIG. 5E) for forming the first (‘lower’) capacitor plate of the MIMCap 512 (only shown in FIG. 5E).

The electrodes 505a, 509c, 509d, 513 may, for example, be formed by first depositing a suitable layer of conductive material, using any appropriate deposition techniques (e.g., by evaporation or sputtering), to an appropriate thickness. The conductive material may, for example, comprise a metal (such as Molybdenum (Mo) or the like) layer having a thickness of 1200 Å or the like. Nevertheless, this is only one example, the conductive layer may comprise other materials as described later. The conductive material of the gate electrodes is then patterned (e.g., using an appropriate mask and photolithographic techniques) to form the gate electrodes.

Turning to FIG. 5C, a second insulating/dielectric layer 504′ is subsequently deposited that covers the semiconducting oxide island(s) 502, the previously formed first insulating/dielectric layer 504a, and the previously formed electrodes 505a, 509c, 509d, 513. It is part of this second insulating/dielectric layer 504b that will ultimately form the gate dielectric of the n-type TFT and the capacitor dielectric of the MIMCap 512 (only shown in FIG. 5E). This second insulating/dielectric layer 504b may, for example, comprise an SiO₂, HfO₂, SiNₓ and/or Al₂O₃ layer (or any suitable combination thereof). Nevertheless, these are only a few examples, the insulating/dielectric layer may comprise other materials as described later. The second insulating/dielectric layer 504b may be of any suitable thickness depending on the material, for example, the dielectric layer may have a thickness of between 100 to 1200 Å. The dielectric layer may also comprise a sub-layer of SiO₂ and a sub-layer of SiNₓ. wherein the thickness of the respective sublayers may be the same or different. The first insulating/dielectric layer 504a and the second insulating/dielectric layer 504b may have different thicknesses and/or may be formed of different materials to one another.

It will be appreciated that the relationship between the thickness of the part of the second insulating/dielectric layer 504b that will ultimately form the gate dielectric of the n-type TFT, and the thickness of the part of the first insulating/dielectric layer 504a that will ultimately form the gate dielectric of the p-type TFT, may be configured to produce similar parasitic gate dielectric capacitances for the n-type and p-type TFTs (e.g., with the lowest value being within 20% (or more preferably 15% or 10%) of the highest value) even when the respective channel lengths are different. It will, nevertheless, be appreciated that in conjunction with (or instead of) gate dielectric thicknesses this similarity in relationship between the parasitic gate dielectric capacitances may be configured by using different dielectrics with different dielectric constants.

The second insulating/dielectric layer 504b is then patterned and etched (e.g., using an appropriate mask and photolithographic techniques) to form an etch stop layer and vias 508a, 508b, through both the first insulating/dielectric layer 504a and the second insulating/dielectric layer 504b to provide for electrical connection to the source and drain regions the p-type TFT when completed. It will be appreciated that the formation of the vias 508a, 508b, may comprise patterning and then etching through the second insulating/dielectric layer 504b (e.g., using a mask and appropriate photolithographic techniques) and then using the patterned second insulating/dielectric layer 504b as a mask for etching through the first insulating/dielectric layer 504a.

As illustrated in FIG. 5D, the structure is then irradiated with electro-magnetic radiation (e.g., with ultraviolet (UV) light). In this example, the electro-magnetic radiation is configured to convert any unshielded semiconducting LTPS, but not any unshielded semiconducting oxide to a higher conductivity (ohmic—e.g., ~1Ω/□) form, for example by appropriate wavelength selection. For example, the irradiation wavelength may be selected such that the electrical properties of the LTPS are changed by the irradiation, but the semiconducting oxide material is not. For example, metal oxide semiconductors such as IGZO are substantially transmissive of wavelengths of greater than ~300 nm, whereas the electrical properties of the crystallised amorphous silicon are affected by UV irradiation at wavelengths of from 300 nm. In one example irradiation from a green laser may be used, for example having a wavelength of 532 nm.

The conversion process may also be contributed to be the release of dopants from surrounding materials. The electro-magnetic radiation is not stopped by the material of the dielectric layer 504a but is stopped by the material of the gate electrode 505a of the p-type TFT. Accordingly, the region of the LTPS island 501 directly below the gate electrode 505a for the p-type TFT is shielded from the electro-magnetic radiation by the material of that gate electrode 505a and remains semiconducting.

Contrastingly, the regions 506a and 506b of the LTPS island 501 for the p-type TFT that are not directly below the corresponding gate electrode 505a are not shielded from the electro-magnetic radiation and are therefore converted. These conducting regions 506a and 506b ultimately become the source and drain regions of the p-type TFT when completed. In this example, whilst the semiconducting oxide island 502 for the n-type are not shielded from the electro-magnetic radiation they are not converted by virtue of the electro-magnetic radiation selected.

As seen in FIG. 5E, following the irradiation, a further layer of conducting material is deposited (e.g., by sputtering). The conductive material may, for example, comprise a metal (such as Molybdenum (Mo) or the like) layer having a thickness of 150 nm or the like. Nevertheless, this is only one example, the conductive layer may comprise other materials as described later. The conductive material is then patterned (e.g., using an appropriate mask and photolithographic techniques) to form: source and drain electrodes 509a and 509b for respectively connecting to source and drain regions 506a and 506b of the p-type TFT via vias 508a and 508b; a gate electrode 505b for the n-type TFT; and a second capacitor electrode 505c for forming the second (‘upper’ or ‘top’) capacitor plate of the MIMCap 512.

It will be appreciated that at this step other metal features (tracking, capacitor plates, etc) may be formed in the same layer. Moreover, this step may (optionally) be used for forming the anode of a metal-semiconductor (Schottky) diode if needed. It will be appreciated that, as those skilled in the art would understand, connection to the previously formed electrodes 505a, 509c, 509d, 513 may be provided by removing the second insulating/dielectric layer 504b (e.g., using a mask and appropriate photolithographic techniques) at appropriate locations.

Accordingly, as seen in FIG. 5E, the integrated electronic circuit comprises an LTPS p-type TFT 510 in conjunction with a semiconductor oxide based n-type TFT 511 that does not share the same gate dielectric as the p-type TFT 510 and a MIMCap 512.

### Illustrative Scenarios

As mentioned above, it has been established that using the techniques introduced, above and described in more detail below, to integrate a relatively small semiconducting oxide (e.g., IGZO) based n-type TFT (e.g., <0.6 μm channel length) with a larger LTPS based p-type TFT (e.g., of ~1 um channel length) can help to: offset the lower mobility of the semiconductor oxide (typically ~10 cm²/V·s, for example, compared with, for example, >50 cm²/V·s for LTPS); reduce and/or offset the different effects of parasitic capacitance; and/or offset differences in gate insulator capacitance. Nevertheless, it will be appreciated that these mobilities, and those recited in the various scenarios below, are exemplary to help illustrate how the ability to integrate smaller semiconducting oxide n-type TFTs, with larger LTPS p-type TFTs (the minimum size of which is limited by grain size), provides benefits in terms of balancing device performance and reducing unwanted parasitic effects. In reality both LTPS and IGZO can have a wide range of carrier mobilities. LTPS, for example, typically has much higher mobilities but could be fabricated to have a lower mobilities (as explained above) by design to help balance CMOS device performance and/or reduce parasitic effects. IGZO could potentially have even lower charge mobilities in some instances.

These benefits will now be further explained, by way of example only with reference to a number of simplified hypothetical scenarios. Each of the scenarios relates to a CMOS pairing of an IGZO n-type TFT with an LTPS p-type TFT. The charge carrier mobility of the IGZO forming the n-type TFT is assumed to be 10 cm²/V·s (e.g., for a gate voltage of 3V) whereas the charge carrier mobility of the LTPS forming the p-type TFT is assumed to be 50 cm²/V·s (e.g., for a gate voltage of −3V).

In these scenarios, performance is measured by reference to three parameters: a parasitic load of gate oxide scaling factor (which scales with the parasitic capacitance associated with the gate insulator (Cₒₓ)); a maximum current (Iₘₐₓ) scaling factor (which scales with the maximum drain-source current (Iₘₐₓ) for a given gate voltage); and the ratio of Iₘₐₓ to Cₒₓ.

As those skilled in the art would understand, in general, for a circuit application requiring complementary p-type and n-type TFTs (e.g., a CMOS based inverter), the parasitic load of gate oxide scaling factor should be similar (ideally the same) for each TFT. Moreover, a lower value of the parasitic load of gate oxide scaling factor is beneficial.

As those skilled in the art would understand, in general, for a circuit application requiring complementary p-type and n-type TFTs (e.g., CMOS), the Iₘₐₓ scaling factor should be similar (ideally the same) for each TFT. A higher value of the Iₘₐₓ scaling factor is beneficial (i.e., representing a higher Iₘₐₓ value). However, if the respective values for the p-type and n-type TFTs are different, it is preferable for the lower performance device (in this example the LTPS n-type TFT) to have the higher value of Iₘₐₓ scaling factor (i.e., representing a higher Iₘₐₓ value) to avoid causing a ‘bottleneck’.

As those skilled in the art would understand, in general, for a circuit application requiring complementary p-type and n-type TFTs (e.g., CMOS), the ratio of Iₘₐₓ to Cₒₓ should be similar (ideally the same) for each TFT. A higher value of the ratio of Iₘₐₓ to Cₒₓ is beneficial.

### Scenario 1

In a first scenario, illustrated in Table 1, the dimensions of the IGZO n-type TFT and the LTPS p-type TFT are the same. The gate insulators of the IGZO n-type TFT and the LTPS p-type TFT are formed of the same material and are of the same thickness. This scenario might arise, for example, where the TFTs share a gate insulator layer.

TABLE 1
Scenario 1

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 1 / 1 = 1 | 1 / 1 = 1 |
| Area (W * L) [μm²] | 1 | 1 |
| Dielectric constant insulator (k) | AlO_{X} (8) | AlO_{X} (8) |
| Dielectric thickness (t) [μm] | 0.02 | 0.02 |
| ‘Parasitic load of gate oxide’ | =1 * 8 / | =1 * 8 / |
| scaling factor | 0.02 = 400 | 0.02 = 400 |
| (Cₒₓ~Area * k / t) | | |
| Iₘₐₓ scaling factor | =10 * 1 * 8 / | =50 * 1 * 8 / |
| (~Mobility * W / L* k / t) | 0.02 = 4000 | 0.02 = 20000 |
| Iₘₐₓ / Cₒₓ | 10 | 50 |

As seen in Table 1, the parasitic load of gate oxide scaling factor of the two TFTs is the same and hence balanced. However, the Iₘₐₓ scaling factor for the n-type TFT is 20% of that of the p-type TFT, and the Iₘₐₓ to Cₒₓ ratio for the n-type TFT is 20% of that of the p-type TFT.

In this scenario, therefore, it can be seen that the inverter performance will be limited by the ‘inferior’ IGZO n-type TFT configuration, because the IGZO n-type TFT limits the Iₘₐₓ.

### Scenario 2

In a second scenario, illustrated in Table 2, the area of the IGZO n-type TFT is five times that of the LTPS p-type TFT by virtue of IGZO n-type TFT having a channel width (and hence a width to length ratio) that is five times that of the LTPS p-type TFT. The gate insulators of the IGZO n-type TFT and the LTPS p-type TFT are formed of the same material and are of the same thickness. This scenario might arise, for example, where the TFTs share a gate insulator layer.

TABLE 2
Scenario 2

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 5 / 1 = 5 | 1 / 1 = 1 |
| Area [μm²] | 5 *1 = 5 | 1 * 1 = 1 |
| Dielectric constant insulator (k) | AlO_{X} (8) | AlO_{X} (8) |
| Dielectric thickness (t) [μm] | 0.02 | 0.02 |
| ‘Parasitic load of gate oxide’ | =5 * 8 / | =1 * 8 / |
| scaling factor | 0.02 = 2000 | 0.02 = 400 |
| (Cₒₓ~Area * k / t) | | |
| Iₘₐₓ scaling factor | =10 * 5 * 8 / | =50 * 1 * 8 / |
| (~Mobility * W / L* k / t) | 0.02 = 20000 | 0.02 = 20000 |
| Iₘₐₓ / Cₒₓ | 10 | 50 |

As seen in Table 2, in this scenario, the Iₘₐₓ scaling factor of the two TFTs is the same and hence balanced. However, the parasitic load of gate oxide scaling factor for the n-type TFT is five times of that of the p-type TFT, and the Iₘₐₓ to Cₒₓ ratio for the n-type TFT is 20% of that of the p-type TFT.

In this scenario, therefore, where the width to length ratio of the lower mobility ‘inferior’ IGZO n-type TFT is scaled up to match the Iₘₐₓ scaling factor of the two TFTs (as would be the conventional approach) to balance the configuration, the inverter performance will be limited by the ‘inferior’ IGZO n-type TFT because of the parasitic load of gate oxide scaling factor for the IGZO n-type TFT is higher.

### Scenario 3

In a third scenario, illustrated in Table 3, the dimensions of the IGZO n-type TFT and the LTPS p-type TFT are the same. However, the gate insulators of the IGZO n-type TFT and the LTPS p-type TFT are formed of different materials with the gate insulator of the IGZO n-type TFT having a dielectric constant (k) that is twice that of the LTPS p-type TFT. The thickness of the gate insulator of the LTPS p-type TFT is assumed to be larger than that of the IGZO n-type TFT for the lower k SiOx material used. This scenario might arise, for example, where the TFTs do not share a gate insulator layer.

TABLE 3
Scenario 3

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 1 / 1 = 1 | 1 / 1 = 1 |
| Area [μm²] | 1 * 1 = 1 | 1 * 1 = 1 |
| Dielectric constant insulator (k) | AlO_{X} (8) | SiO_{X} (4) |
| Dielectric thickness (t) [μm] | 0.02 | 0.05 |
| ‘Parasitic load of gate oxide’ | =1 * 8 / | =1 * 4 / |
| scaling factor | 0.02 = 400 | 0.05 = 80 |
| (Cₒₓ~Area * k / t) | | |
| Iₘₐₓ scaling factor | =10 * 1 * 8 / | =50 * 1 * 4 / |
| (~Mobility * W / L* k / t) | 0.02 = 4000 | 0.05 = 4000 |
| Iₘₐₓ / Cₒₓ | 10 | 50 |

As seen in Table 3, in this scenario, the Iₘₐₓ scaling factor of the two TFTs is the same and hence balanced. However, the Iₘₐₓ scaling factor is lower than in scenario 2. The parasitic load of gate oxide scaling factor for the n-type TFT is five times of that of the p-type TFT, and the Iₘₐₓ to Cₒₓ ratio for the n-type TFT is 20% of that of the p-type TFT.

In this scenario, therefore, the LTPS p-type TFT has a lower dielectric constant (k) insulator (SiOx) with a greater thickness (which is commonly used for LTPS TFTs). In this scenario however, the inverter performance will still be limited by the ‘inferior’ IGZO n-type TFT because of the parasitic load of gate oxide scaling factor for the IGZO n-type TFT is higher. Additionally, the inverter performance will be limited by the lower Iₘₐₓ scaling factor of the LTPS p-type TFT.

### Scenario 4

In a fourth scenario, illustrated in Table 4, the area of the IGZO n-type TFT is 20% that of the LTPS p-type TFT by virtue of IGZO n-type TFT having a channel length that is 20% that of the LTPS p-type TFT. The gate insulators of the IGZO n-type TFT and the LTPS p-type TFT are formed of the same material and are of the same thickness. This scenario might arise, for example, where the TFTs share a gate insulator layer.

TABLE 4
Scenario 4

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 1 / 0.2 = 5 | 1 / 1 = 1 |
| Area [μm²] | 1 * 0.2 = 0.2 | 1 * 1 = 1 |
| Dielectric constant insulator (k) | AlO_{X} (8) | AlO_{X} (8) |
| Dielectric thickness (t) [μm] | 0.02 | 0.02 |
| ‘Parasitic load of gate oxide’ | =0.2 * 8 / | =1 * 8 / |
| scaling factor | 0.02 = 80 | 0.02 = 400 |
| (Cₒₓ~Area * k / t) | | |
| Iₘₐₓ scaling factor | =10 * 5 * 8 / | =50 * 1 * 8 / |
| (~Mobility * W / L* k / t) | 0.02 = 20000 | 0.02 = 20000 |
| Iₘₐₓ / Cₒₓ | 250 | 50 |

As seen in Table 4, in this scenario, the Iₘₐₓ scaling factor of the two TFTs is the same and hence balanced and significantly higher than the previous scenario. The parasitic load of gate oxide scaling factor for the p-type TFT is 20% that of the p-type TFT, and the Iₘₐₓ to Cₒₓ ratio for the n-type TFT is five times that of that of the p-type TFT.

This scenario, therefore, takes advantage of the ability to scale down the size of the IGZO n-type TFT below that of the LTPS p-type TFT to ensure that the inverter performance is no longer limited by the low mobility IGZO n-type TFT. In this case, therefore, it is the parasitic load of LTPS p-type TFT that becomes limiting factor and the IGZO n-type TFT is no longer the bottleneck.

### Scenario 5

In a fifth scenario, illustrated in Table 5, the area of the IGZO n-type TFT is 20% that of the LTPS p-type TFT by virtue of IGZO n-type TFT having a channel length that is 20% that of the LTPS p-type TFT. However, the gate insulators of the IGZO n-type TFT and the LTPS p-type TFT are formed of different materials with the gate insulator of the IGZO n-type TFT having a dielectric constant (k) that is twice that of the LTPS p-type TFT. The thickness of the gate insulator of the LTPS p-type TFT is, however, the same as that of the IGZO n-type TFT. This scenario might arise, for example, where the TFTs do not share a gate insulator layer.

TABLE 5
Scenario 5

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 1 / 0.2 = 5 | 1 / 1 = 1 |
| Area [μm²] | 1 * 0.2 = 0.2 | 1 * 1 = 1 |
| Dielectric constant insulator (k) | AlO_{X} (8) | SiO_{X} (4) |
| Dielectric thickness (t) [μm] | 0.02 | 0.02 |
| ‘Parasitic load of gate oxide’ | =0.2 * 8 / | =1 * 4 / |
| scaling factor | 0.02 = 80 | 0.02 = 200 |
| (Cₒₓ~Area * k / t) | | |
| Iₘₐₓ scaling factor | =10 * 5 * 8 / | =50 * 1 * 4 / |
| (~Mobility * W / L* k / t) | 0.02 = 20000 | 0.02 = 10000 |
| Iₘₐₓ / Cₒₓ | 250 | 50 |

As seen in Table 5, in this scenario, the Iₘₐₓ scaling factor of the n-type TFT is twice that of the p-type TFT. The Iₘₐₓ scaling factor of the p-type TFT is lower than in the previous scenario but still relatively high. The parasitic load of gate oxide scaling factor for the p-type TFT is 40% that of the p-type TFT (and hence they are closer to one another). The Iₘₐₓ to Cₒₓ ratio for the n-type TFT is five times that of that of the p-type TFT.

This scenario, therefore, also takes advantage of the ability to scale down the size of the IGZO n-type TFT below that of the LTPS p-type TFT to ensure that the inverter performance is no longer limited by the low mobility IGZO n-type TFT. In this case, therefore, it is the parasitic load of LTPS p-type TFT that becomes limiting factor and the IGZO n-type TFT is no longer the bottleneck.

### Scenario 6

In a sixth scenario, illustrated in Table 6, the area of the IGZO n-type TFT is 20% that of the LTPS p-type TFT by virtue of IGZO n-type TFT having a channel length that is 20% that of the LTPS p-type TFT. However, the gate insulators of the IGZO n-type TFT and the LTPS p-type TFT are formed of different materials with the gate insulator of the IGZO n-type TFT having a dielectric constant (k) that is twice that of the LTPS p-type TFT. The thickness of the gate insulator of the LTPS p-type TFT is assumed to be larger than that of the IGZO n-type TFT for the lower k SiOx material used. This scenario might arise, for example, where the TFTs do not share a gate insulator layer.

TABLE 6
Scenario 6

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 1 / 0.2 = 5 | 1 / 1 = 1 |
| Area [μm²] | 1 * 0.2 = 0.2 | 1 * 1 = 1 |
| Dielectric constant insulator (k) | AlO_{X} (8) | SiO_{X} (4) |
| Dielectric thickness (t) [μm] | 0.02 | 0.05 |
| ‘Parasitic load of gate oxide’ | =0.2 * 8 / | =1 * 4 / |
| scaling factor | 0.02 = 80 | 0.05 = 80 |
| (Cₒₓ~Area * k / t) | | |
| Iₘₐₓ scaling factor | =10 * 5 * 8 / | =50 * 1 * 4 / |
| (~Mobility * W / L* k / t) | 0.02 = 20000 | 0.05 = 4000 |
| Iₘₐₓ / Cₒₓ | 250 | 50 |

As seen in Table 6, the parasitic load of gate oxide scaling factor of the two TFTs is the same and hence balanced. However, in this scenario, the Iₘₐₓ scaling factor of the n-type TFT is five times that of the p-type TFT and the Iₘₐₓ scaling factor of the p-type TFT is lower than in previous scenarios. The Iₘₐₓ to Cₒₓ ratio for the n-type TFT is five times that of that of the p-type TFT.

This scenario, therefore, also takes advantage of the ability to scale down the size of the IGZO n-type TFT below that of the LTPS p-type TFT to ensure that the inverter performance is no longer limited by the low mobility IGZO n-type TFT. In this case, therefore, it is the parasitic load of LTPS p-type TFT that becomes limiting factor and the IGZO n-type TFT is no longer the bottleneck.

### Scenario 7

In a seventh scenario, illustrated in Table 7, the area of the IGZO n-type TFT is 40% that of the LTPS p-type TFT by virtue of IGZO n-type TFT having a channel length that is 40% that of the LTPS p-type TFT. The gate insulators of the IGZO n-type TFT and the LTPS p-type TFT are formed of different materials with the gate insulator of the IGZO n-type TFT having a dielectric constant (k) that is twice that of the LTPS p-type TFT. The thickness of the gate insulator of the LTPS p-type TFT is assumed to be larger than that of the IGZO n-type TFT for the lower k SiOx material used. This scenario might arise, for example, where the TFTs do not share a gate insulator layer.

TABLE 7
Scenario 7

| | Indium Gallium | Low-temperature |
|---|---|---|
| | Zinc oxide | polycrystalline |
| Property | (IGZO) | Silicon (LTPS) |
| Mobility [cm²/V · s] | 10 | 50 |
| Width (W) / Length (L) [μm/μm] | 1 / 0.4 = 2.5 | 1 / 1 = 1 |
| Area [μm²] | 1 * 0.4 = 0.4 | 1 * 1 = 1 |
| Dielectric constant insulator (k) | AlO_{X} (8) | SiO_{X} (4) |
| Dielectric thickness (t) [μm] | 0.04 | 0.05 |
| ‘Parasitic load of gate oxide’ | =0.2 * 8 / | =1 * 4 / |
| scaling factor | 0.04 = 80 | 0.05 = 80 |
| (Cₒₓ~Area * k / t) | | |
| Iₘₐₓ scaling factor | =10 * 5 * 8 / | =50 * 1 * 4 / |
| (~Mobility * W / L* k / t) | 0.04 = 5000 | 0.05 = 4000 |
| Iₘₐₓ / Cₒₓ | 62.5 | 50 |

As seen in Table 7, the parasitic load of gate oxide scaling factor of the two TFTs is the same and hence balanced. Moreover, in this scenario, the Iₘₐₓ scaling factor of the n-type TFT is higher than but still close to that of the p-type TFT and hence is near balanced. Moreover, the Iₘₐₓ to Cₒₓ ratio for the n-type TFT is close that of that of the p-type TFT. The Iₘₐₓ scaling factor of the p-type TFT is lower than in previous scenarios, but this is offset by the balancing between the two devices.

This scenario, therefore, also takes advantage of the ability to scale down the size of the IGZO n-type TFT below that of the LTPS p-type TFT to ensure that the inverter performance is no longer limited by the low mobility IGZO n-type TFT. The IGZO n-type TFT IGZO is, therefore, not the limiting factor and the close match between the LTPS p-type TFT and the IGZO n-type TFT by virtue of the control of the dimensions (including gate insulator thickness) of the IGZO n-type TFT.

### SUMMARY

In summary, therefore, it can be seen that the ability to control the size of the IGZO n-type TFT (as well as thickness) to be smaller than that of the LTPS TFT (the minimum size of which is limited by the grain size of the LTPS) can be used beneficially, to help avoid the limitations arising from the lower IGZO mobility and to ensure balanced complementary TFTs despite the differences between the underlying materials used to manufacture them.

It will be appreciated that the relationship between the dimensions (length and/or width) of the channel regions/channels of the n-type TFT, and the dimensions (length and/or width) of the channel regions/channels of the p-type TFT, may be configured to produce similar performance characteristics for the n-type and p-type TFTs (e.g., a maximum drain source current Iₘₐₓ for a given gate voltage magnitude), for example with the lowest value being within 25% (or more preferably 20%, 15% or 10%) of the highest value. It will also be appreciated that the relationship between the dimensions (length and/or width) of the channel regions/channels of the n-type TFT, and the dimensions (length and/or width) of the channel regions/channels of the p-type TFT, may be configured to ensure that if the performance characteristics for the n-type and p-type TFTs (e.g., a maximum drain source current Iₘₐₓ for a given gate voltage magnitude) are not the same, the n-type TFT has the superior performance characteristic (e.g., highest maximum drain source current Iₘₐₓ for a given gate voltage magnitude).

### Modifications & Alternatives

Detailed examples been described above. As those skilled in the art will appreciate, a number of modifications and alternatives can be made to the above examples whilst still benefiting from the enhancements embodied therein.

It will be appreciated, for example, that whilst TFT channel lengths of <1 μm are difficult to achieve using higher mobility LTPS, lower mobility LTPS may have much smaller grains thereby allowing smaller p-type TFTs to be fabricated (e.g., with channel lengths potentially as low as between 0.05 μm and 0.6 μm). This may be used in the above examples to help offset some of the performance loss arising from using a lower mobility material to help balance complementary TFTs. This could, for example, allow n-type and p-type TFTs of similar dimensions to be made respectively from semiconducting oxide and LTPS materials having similar mobilities, that provide a similar performance, and that exhibit similar parasitic effects (hence avoiding the need to use different dimension devices).

It will also be appreciated that whilst the procedures described above the layer of amorphous silicon is processed to form LTPS before patterning takes place, patterning could potentially take place while the silicon is still amorphous and patterning could take place afterwards. Moreover, rather than deposit, crystallise and then pattern the amorphous silicon, a variant could involve depositing a blanket layer of amorphous silicon (which may then be crystallised), and then at least one blanket dielectric layer, before patterning them both using the same mask. This would allow the upper surface (and hence gate interface) of the amorphous/polycrystalline silicon in the channel to be pristine (i.e. unaffected by the patterning process). The n-type material could then be deposited onto the same substrate as the p-type material is located.

It can be seen that in accordance with the above description, there is provided an electronic circuit (IC) comprising a thin film transistor (TFT), wherein the TFT is a p-type TFT and comprises a first semiconductor body made from low temperature polysilicon (LTPS), which may comprise a channel region for forming a channel of length from 0.5 to 20 μm.

The channel length may be from 0.1 to 19.5 μm, for example, from 0.15 to 18.5 μm, 0.2 to 18 μm, 0.25 to 17.5 μm, 0.3 to 17 μm, 0.35 to 16.5 μm, 0.4 to 16 μm, 0.45 to 15.5 μm, 0.5 to 15 μm, 0.55 to 14.5 μm, 0.6 to 14 μm, 0.65 to 13.5 μm, 0.7 to 13 μm, 0.75 to 12.5 μm, 0.8 to 12 μm, 0.85 to 11.5 μm, 0.9 to 11 μm, 0.95 to 10 μm, or 1 to 9.5 μm.

The channel length may be from 0.05 to 9 μm, such as, for example, from 0.055 to 5 μm, 0.1 to 4.5 μm, 0.15 to 4 μm, 0.2 to 3.5 μm, 0.25 to 3 μm, 0.3 to 2.5 μm, 0.35 to 2 μm, 0.4 to 1.5 μm. For example, the channel length may be from 0.05 to 0.6 μm, for example, from 0.1 to 0.55 μm, 0.15 to 0.5 μm, 0.2 to 0.45 μm, 0.25 to 0.4 μm, 0.3 to 0.35 μm.

The p-type TFT may have a channel region and/or source and drain regions that are formed of doped LTPS. The doping may, for example, comprise one or more of phosphorous ions, BF₂ ions, or any other dopants or doping ions known to the person skilled in the art.

The channel region of the p-type TFT may have a charge carrier mobility of between 1 and 200 cm²/V·s.

The channel region of the p-type TFT may have a charge carrier mobility of from 0.5 and 500 cm²/V·s, for example, from 1.5 to 195 cm²/V·s, 2 to 190 cm²/V·s, 2.5 to 185 cm²/V·s, 3 to 180 cm²/V·s, 3.5 to 175 cm²/V·s. 4 to 170 cm²/V·s, 5 to 165 cm²/V·s, 5.5 to 160 cm²/V·s, 6 to 155 cm²/V·s, 6.5 to 150 cm²/V·s, 7 to 145 cm²/V·s, 7.5 to 140 cm²/V·s, 8 to 135 cm²/V·s, 8 to cm²/V·s, 130 cm²/V·s, 8.5 to 125 cm²/V·s, 9 to 120 cm²/V·s, 9.5 to 115 cm²/V·s, 10 to 110 cm²/V·s, 10.5 to 105 cm²/V·s, 11 to 100 cm²/V·s, 11.5 to 95 cm²/V·s, 12 to 90 cm²/V·s, or 12.5 to 85 cm²/V·s.

The charge carrier mobility of the LTPS may, for example, have charge mobility of from 1 to 40 cm²/V·s, such as, for example, 1.5 to 39 cm²/V·s, 2 to 38 cm²/V·s, 2.5 to 37 cm²/V·s, 3 to 36 cm²/V·s, 3.5 to 35.5 cm²/V·s, 4 to 35 cm²/V·s, 4.5 to 35 cm²/V·s, 5 to 34 cm²/V·s, 5.5 to 33 cm²/V·s, 6 to 32 cm²/V·s, 6.5 to 31 cm²/V·s, 7 to 30 cm²/V·s, 7.5 to 29 cm²/V·s, 8 to 28 cm²/V·s, 8.5 to 27 cm²/V·s, 9 to 26 cm²/V·s, 9.5 to 25 cm²/V·s, 10 to 24 cm²/V·s, or 11 to 23 cm²/V·s.

The channel region of the p-type TFT may have a charge carrier mobility of from 1 to 30 cm²/V·s, such as, for example, 1.5 to 29 cm²/V·s, 2 to 28 cm²/V·s, 2.5 to 27 cm²/V·s, 3 to 26 cm²/V·s, 3.5 to 25.5 cm²/V·s, 4 to 25 cm²/V·s, 4.5 to 25 cm²/V·s, 5 to 24 cm²/V·s, 5.5 to 23 cm²/V·s, 6 to 22 cm²/V·s, 6.5 to 21 cm²/V·s, 7 to 20 cm²/V·s, 7.5 to 19 cm²/V·s, 8 to 18 cm²/V·s, 8.5 to 17 cm²/V·s, 9 to 16 cm²/V·s, 9.5 to 15 cm²/V·s, 10 to 14 cm²/V·s, or 11 to 13 cm²/V·s.

The electronic circuit may comprise a first terminal and a second terminal. The first and second terminal may be formed from the same or different materials. One or both of the first terminal and the second terminal may be formed from one or more of: LTPS, doped LTPS, Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; or semiconductor materials. Preferably, one or both of the first and second terminals are formed from LTPS or doped LTPS.

The first terminal may be provided at a first terminus of the channel region of the p-type TFT, and the second terminal may be provided at second end of the channel region of the p-type TFT opposite to the first terminus. The first terminal, the LTPS channel region and the second terminal may be contiguous. A portion of a first terminal region of the first semiconductor body may overlap with the first terminal. At least a portion of a second terminal region of the first semiconductor body may overlap with the second terminal. At least a portion of the first terminal region and at least a portion of the second terminal region of the semiconductor body may overlap with the first and second terminal respectively.

The first semiconductor body may comprise the first terminal and the second terminal in a first terminal region and a second terminal region respectively. The first and second terminal regions may be formed by selective treatment of the first and second terminal regions of the first semiconductor body. The selective treatment may include irradiation, or thermal or laser annealing of the first and second terminal regions of the first semiconductor body. Irradiation may be selective UV irradiation.

A channel length, L, of the p-type TFT may be defined by the distance between the first and second terminals or the distance between the first terminal region and the second terminal region.

The p-type TFT may further comprise a gate electrode.

The p-type TFT gate electrode may be formed from a material selected from one or more of: Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; or semiconductor materials such as amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃.

The p-type TFT gate electrode may be formed from one or more of: amorphous, polycrystalline, microcrystalline or nanocrystalline silicon.

As described above in relation to FIGS. 1F, 2F, 3F, 4F, and 5E, the p-type TFT may be provided on a substrate. The p-Type TFT may comprise a channel region, a first terminal, a second terminal, an insulating layer provided over the first terminal, the second terminal and the channel region, a source electrode and a drain electrode provided in contact vias. A gate electrode may be provided over the channel region, on the insulating layer. The channel region may provide for a channel length, L, of from 0.05 to 0.6 μm, and a charge carrier mobility of from 1 to 40 cm²/V·s, as mentioned above.

The source and the drain electrodes may be formed from layers of one more conductive or semiconductive materials selected from one or more of: Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnₓO_{y}N_{z}; inorganic semiconductors, such as amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃.

The electronic circuit may comprise, or may further comprise, one or more of a second TFT, a resistor and a capacitor.

The electronic circuit may comprise, or may further comprise, one or more of a second p-type TFT, an n-type TFT, a first type of resistor, a second type of resistor, a semiconductor-insulator-metal capacitor (SIMCap) or a metal-insulator-metal capacitor (MIMCap).

Where the electronic circuit further comprises a first type of resistor, the first type of resistor may comprise a resistor body made from the LTPS used to form the first semiconductor body of the p-type TFT.

The first type of resistor may comprise a third terminal and a fourth terminal. The third and fourth terminal may be formed from the same or different materials. One or both of the first terminal and the second terminal may be formed from one or more of: LTPS, doped LTPS, Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; or semiconductor materials. Preferably, one or both of the third and fourth terminals are formed from LTPS or doped LTPS.

The resistor body may comprise the third terminal and the fourth terminal in a first terminal region of the resistor body and a second terminal region of the resistor body respectively. The first and second terminal regions may be formed by selective treatment of the first and second terminal regions of the resistor body. The selective treatment may include irradiation, or thermal or laser annealing of the first and second terminal regions of the resistor body. Irradiation may be selective UV irradiation.

As described with reference to FIG. 1F in particular, in one example of the electronic circuit in accordance with the present disclosure, the electronic circuit comprises a p-type TFT, and a first type of resistor provided on a substrate. The p-Type TFT comprises a channel region, a first terminal, a second terminal, an insulating layer provided over the first terminal, the second terminal and the channel region, a source electrode and a drain electrode provided in corresponding contact vias. A gate electrode is provided over the channel region, on the insulating layer. The channel region is configured to provide a channel length, L, of from 0.05 to 0.6 μm, and a charge carrier mobility of from 1 to 40 cm²/V·s, as mentioned above. The first type of resistor comprises a resistor body, an insulating layer provided over the semiconductor body, a first electrode and a second electrode provided in corresponding contact vias.

Where the electronic circuit comprises, or further comprises, a SIMCap, then the SIMCap may comprise a semiconductor capacitor plate which may be made from the LTPS used for the p-type TFT.

The SIMCap may comprise, for example, a first capacitor contact. The first capacitor contact may be provided over at least a portion of the semiconductor capacitor plate. The first capacitor contact may be provided over the semiconductor capacitor plate. The first capacitor contact may be provided over a substantial portion of the semiconductor capacitor plate. The first capacitor contact may be provided at least partially over the semiconductor capacitor plate. The first capacitor contact may be completely provided over the semiconductor capacitor plate. The first capacitor contact may be formed from one or more of: LTPS, doped LTPS, Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; or semiconductor materials.

The resistor body of the first type of resistor and/or the semiconductor capacitor plate of the SIMCap may have a lower resistivity than the channel region of the first p-type TFT.

As described with reference to FIG. 3F in particular, in one example of the electronic circuit in accordance with the present disclosure, the electronic circuit comprises a p-type TFT, and a SIMCap (semiconductor-insulator-metal capacitor or SIMCap) provided on a substrate. The p-Type TFT comprises a channel region, a first terminal, a second terminal, an insulating layer provided over the first terminal, the second terminal and the channel region, a source electrode and a drain electrode provided in corresponding contact vias. A gate electrode is provided over the channel region, on the insulating layer. The channel region is configured to provide a channel length, L, of from 0.05 to 0.6 μm, and a charge carrier mobility of from 1 to 40 cm²/V·s, as mentioned above. The SIMCap comprises a semiconductor body, an insulating layer provided over the semiconductor body, a first capacitor electrode, a second capacitor electrode provided in a corresponding contact via, and a capacitor top contact (vertical contact) provided at least partially over semiconductor body. The capacitor top contact also serves as a capacitor top plate and is provided at least partially over the semiconductor body, which serves as a lower capacitor plate. A further capacitor contact makes electrical contact with this lower capacitor plate.

Where the electronic circuit comprises, or further comprises, an n-type TFT, the n-type TFT may comprise an n-type TFT semiconductor body.

The n-type TFT may comprise a fifth terminal and a sixth terminal. The n-type TFT semiconductor body may further comprise the fifth and sixth terminal. The fifth terminal may be provided at a first terminus of the n-type TFT semiconductor body, and the second terminal may be provided at second terminus of the n-type TFT semiconductor body opposite to the first terminus. The fifth terminal, the n-type TFT semiconductor body and the sixth terminal may be contiguous. A portion of a first terminal region of the n-type TFT semiconductor body may overlap with the fifth terminal. At least a portion of a second terminal region of the n-type TFT semiconductor body may overlap with the sixth terminal. At least a portion of the first terminal region and at least a portion of the second terminal region of the n-type TFT semiconductor body may overlap with the fifth and sixth terminals respectively. The n-type TFT semiconductor body may comprise the fifth terminal and the sixth terminal in a first terminal region and a second terminal region respectively. The first and second terminal regions may be formed by selective treatment of the first and second terminal regions of the n-type TFT semiconductor body. The selective treatment may include irradiation, or thermal or laser annealing of the first and second terminal regions of the first semiconductor body. The irradiation may be selective UV irradiation.

The n-type TFT may further comprise a gate electrode.

The n-type TFT gate electrode may be formed from a material selected from one or more of: Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnₓO_{y}N_{z}; inorganic semiconductors, such as amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃.

Where, as mentioned above, the electronic circuit comprises a p-type TFT and an n-Type TFT, the p-type TFT and n-type TFT may be stacked vertically (not shown). Nevertheless, the p-type TFT and n-type TFT may be provided laterally in relation to one another (as shown in and described with reference to FIGS. 2F, 4F and 5E). A p-type TFT and an n-type TFT that are provided laterally relative to one another may be provided in the same lateral plane (as shown in and described with reference FIG. 2F) or different lateral planes (as shown in and described with reference to FIGS. 4F and 5E).

As described above, the electronic circuit may comprise a hybrid complementary metal oxide semiconductor (CMOS) circuit, which may comprise a p-type TFT and an n-type TFT according to the present disclosure.

As described with reference to FIG. 2F in particular, in one example of the electronic circuit in accordance with the present disclosure, a p-type TFT, and n-type TFT are provided on a substrate. The p-Type TFT, and n-type TFT of this example are provided in the same plane. The p-Type TFT comprises: a channel region, a first terminal, a second terminal, an insulating layer provided over the first terminal, the second terminal and the channel region; a source electrode and a drain electrode provided in contact corresponding vias. A gate electrode is provided over the channel region, on the insulating layer. The channel region is configured to provide a channel length, L, of between 0.05 and 0.6 μm, and a charge carrier mobility of between 1 and 40 cm²/V·s, as mentioned above. The n-type TFT comprises an n-type TFT semiconductor body, a fifth terminal, a sixth terminal, an insulating layer provided over the n-type TFT semiconductor body, a source electrode and a drain electrode provided in corresponding contact vias.

As described with reference to FIG. 4F in particular, in one example of the electronic circuit in accordance with the present disclosure, the electronic circuit comprises a p-type TFT provided on a substrate, and an n-type TFT provided on an insulator layer, which is also provided on the substrate. The p-type TFT and n-type TFT are, therefore, not in the same plane and are laterally displaced in relation to one another. The p-Type TFT comprises a channel region, a first terminal, a second terminal, an insulating layer provided over the first terminal (which is also the insulating layer on which the n-type TFT is formed), the second terminal and the channel, a source electrode and a drain electrode provided in corresponding contact vias. A gate electrode is provided over the channel, on the insulating layer. The channel region is configured to provide a channel length, L, of from 0.05 to 0.6 μm, and a charge carrier mobility of between 1 and 40 cm²/V·s, as mentioned above. The n-type TFT comprises an n-type TFT semiconductor body, the fifth terminal, the sixth terminal, a further insulating layer provided over the n-type TFT semiconductor body, a source electrode and a drain electrode provided in corresponding contact vias.

Where the electronic circuit further comprises a second type of resistor, the second type of resistor may comprise a second type of resistor body made from the same material used to form the n-type TFT semiconductor body.

The second type of resistor may comprise a seventh terminal and an eighth terminal. The seventh terminal may be provided at a first terminus of the second type of resistor's resistor body, and the second terminal may be provided at second terminus of the second type of resistor's resistor body opposite to the first terminus. The seventh terminal, the second type of resistor's resistor body and the eighth terminal may be contiguous. A portion of a first terminal region of the second type of resistor's resistor body may overlap with the seventh terminal. At least a portion of a second terminal region of the second type of resistor's resistor body may overlap with the eighth terminal. At least a portion of the first terminal region and at least a portion of the second terminal region of the second type of resistor's resistor body may overlap with the seventh and eighth terminals respectively.

The second type of resistor's resistor body may further comprise the seventh and eighth terminal. The second type of resistor's resistor body comprises the seventh terminal and the eighth terminal in a first terminal region and a second terminal region respectively. The first and second terminal regions may be formed by selective treatment of the first and second terminal regions of the n-type semiconductor body. The selective treatment may include irradiation, or thermal or laser annealing of the first and second terminal regions of the first semiconductor body. Irradiation may be selective UV irradiation.

The electronic circuit may comprise, or further comprise, an MIMCap. The MIMCap may comprise an insulator or dielectric body.

The insulator or dielectric body of the MIMCap may formed from one or more dielectric materials selected from one or more of: Al₂O₃, ZrO₂, HfO₂, Y₂O₃, Si₃N₅, TiO₂, Ta₂O₅; metal phosphates such as Al₂POₓ; metal sulphates/sulphites such as HfSOₓ; metal nitrides such as AlN; metal oxynitride such as AlOₓN_{y}; inorganic insulators such as SiO₂, Si₃N₄, SiNₓ; spin on glass (such as polyhydroxybenzyl silsesquioxane, HSQ), polymeric dielectric materials (such as Cytop, a commercially available amorphous fluoropolymer), 1-Methoxy-2-propyl acetate (SU-8), benzocyclobutene (BCB), polyimide, polymethyl methacrylate, polybutyl methacrylate, polyethyl methacrylate, polyvinyl acetate, polyvinyl pyrrolidone, polyvinylphenol, polyvinylchloride, polystyrene, polyethylene, polyvinyl alcohol, polycarbonate, parylene, silicone; UV-curable resins; Nanoimprint resists; or photoresists. The dielectric material may have a relatively low dielectric constant (low-κ, e.g. Cytop, HSQ, parylene) or a relatively high dielectric constant (high-κ, e.g. Ta₂O₅, HfO₂), or any other insulating oxides, oxynitrides, silicates, etc. The semiconductor body of the MIMCap may be formed from one or more layers of metal such as, for example, titanium, steel, gold, etc. The semiconductor body may provide control over the movement of chemical elements, such as metals, hydrogen or oxygen, into or out of the component layer of the flexible ICs.

The MIMCap may comprise a first capacitor (or ‘vertical’) contact (top contact). The first capacitor contact may be provided over at least a portion of the MIMCap's semiconductor body. The MIMCap contact may be provided over the n-type semiconductor body. The first capacitor contact may be provided over a substantial portion of the MIMCap's semiconductor body. The first capacitor contact may be provided at least partially over the first capacitor semiconductor body. The first capacitor contact may be completely provided over the n-type semiconductor body. The first capacitor contact may be formed from one or more of: Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; semiconductor materials, GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnₓO_{y}N_{z}; inorganic semiconductors, organic semiconductors, such as, CuPc, pentacene, PTCDA, methylene blue, Orange G, rubrene; polymer semiconductors, such as, PEDOT:PSS, POT, P3OT, P₃HT, polyaniline, polycarbazole; 2D materials, such as, graphene; chalcogenides, such as, MoS₂.

As described with reference to FIG. 5E in particular, in one example of the electronic circuit in accordance with the present disclosure, the electronic circuit comprises a p-type TFT provided on a substrate, an n-type TFT, and a MIMCap. The n-type TFT, and MIMCap are provided on an insulator layer (which serves as the gate dielectric of the p-type TFT), which in turn is provided on the substrate. The p-Type TFT comprises a channel, a first terminal, a second terminal, an insulating layer provided over the first terminal, the second terminal and the channel, a source electrode and a drain electrode provided in corresponding contact vias. A gate electrode is provided over the channel region, on the insulating layer. The channel region is configured to provide a channel length, L, of from 0.05 to 0.6 μm, and a charge carrier mobility of from 1 to 40 cm²/V·s, as mentioned above. The n-type TFT comprises an n-type TFT semiconductor body, an insulating layer provided over the n-type TFT semiconductor body, a source electrode, and a drain electrode. The MIMCap comprises a lower electrode plate provided on the substrate, an insulating layer provided over the lower electrode plate and a capacitor top contact provided over lower electrode plate, on insulating layer.

The insulating layers described herein, such as insulator layers 104, 204, 304, 404a, 404b, 504a, and 504b, may be formed from one or more dielectric materials and/or dielectric layers, examples of which include metal oxides such as Al₂O₃, ZrO₂, HfO₂, Y₂O₃, Si₃N₅, TiO₂, Ta₂O₅; metal phosphates such as Al₂POₓ; metal sulphates/sulphites such as HfSOₓ; metal nitrides such as AlN; metal oxynitride such as AlOₓN_{y}; inorganic insulators such as SiO₂, Si₃N₄, SiNₓ; spin on glass (such as polyhydroxybenzyl silsesquioxane, HSQ), polymeric dielectric materials (such as Cytop, a commercially available amorphous fluoropolymer), 1-Methoxy-2-propyl acetate (SU-8), benzocyclobutene (BCB), polyimide, polymethyl methacrylate, polybutyl methacrylate, polyethyl methacrylate, polyvinyl acetate, polyvinyl pyrrolidone, polyvinylphenol, polyvinylchloride, polystyrene, polyethylene, polyvinyl alcohol, polycarbonate, parylene, silicone; UV-curable resins; Nanoimprint resists; or photoresists. The dielectric material may have a relatively low dielectric constant (low-κ, e.g. Cytop, HSQ, parylene) or a relatively high dielectric constant (high-κ, e.g. Ta₂O₅, HfO₂), or any other insulating oxides, oxynitrides, silicates, etc. The insulator layer may provide control over the movement of chemical elements, such as metals, hydrogen or oxygen, into or out of the component layer of the flexible ICs. The insulating layers, such as insulator layer 104, 204, 304, 404a, 404b, 504a, 505′ may be formed from one or more of: SiO₂, HfO₂, and Al₂O₃.

As explained above, the substrate may further comprise a barrier layer (which may also be referred to as an interface layer (interlayer)), wherein the p-type TFT is provided on an upper surface said barrier layer (interface layer or interlayer). The upper surface of the barrier layer (interface layer or interlayer) lies generally parallel with the upper surface of the substrate, upon which the previously mentioned electrical components are formed or provided.

If a barrier layer is provided on the substrate (e.g., between the component devices and the substrate) it may comprise, one or more of: metal oxides such as Al₂O₃, ZrO₂, HfO₂, Y₂O₃, Si₃N₅, TiO₂, Ta₂O₅ or any other suitable metal oxide; or metal phosphates such as Al₂POₓ or any other suitable metal phosphate; metal sulphates or metal sulphites such as HfSOₓ or any other suitable metal sulphate or metal sulphite; metal nitrides such as AlN, TiN, ZrN, TaN, HfN or any other suitable metal nitride; metal oxynitrides such as AlOₓN_{y} or any other suitable metal oxynitride; inorganic insulators such as SiO₂, Si₃N₄, SiNₓ or any other suitable inorganic insulator; spin on glass such as polyhydroxybenzyl silsesquioxane or any other suitable spin on glass; or polymeric dielectric materials such as amorphous fluoropolymers (Cytop®), Bisphenol A novolac epoxy (SU-8), benzocyclobutenes (BCB), polyimides, polymethyl methacrylates, polybutyl methacrylates, polyethyl methacrylates, polyvinyl acetates, polyvinyl pyrrolidones, polyvinyl alcohols, polyvinyl phenols, polyvinyl chlorides, polystyrenes, polyethylenes, polycarbonates, parylenes, silicone, or any other suitable polymeric dielectric materials. It will be appreciated that the materials listed herein are only provided by way of example and are not an exhaustive list of possible materials that may be used for the barrier layer.

The second type of resistor bodies maybe formed from semiconductor materials selected from one or more of: GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnxOyNz; inorganic semiconductors, such as, amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃. These semiconductor materials may also be doped or contain a doping gradient. Further treatments may be applied to the component layers to modify their semiconductor properties such as annealing (thermal, laser). In some embodiments, the n-type resistor bodies may be formed from IGZO.

As mentioned above, the substrate may be a flexible substrate. The substrate may, for example, be formed from one or more materials selected from: polyethylene naphthalate, polyethylene terephthalate; polymethyl methacrylate; polycarbonate, polyvinyl alcohol; polyvinyl acetate; polyvinyl pyrrolidone; polyvinyl phenol; polyvinyl chloride; polystyrene; polyimide, polyamide (e.g. Nylon); poly(hydroxyether); polyurethane; polysulfone; parylene; polyarylate; polyether ether ketone (PEEK); acrylonitrile butadiene styrene; 1-Methoxy-2-propyl acetate (SU-8); polyhydroxybenzyl silsesquioxane (HSQ); Benzocyclobutene (BCB); UV-curable resin; Nanoimprint resist; photoresist; polymeric foil; paper; insulator-coated metal (e.g. coated stainless-steel); and cellulose.

As explained above electronic circuit being formed is an integrated circuit (IC). The electronic circuit may be a thin-film IC and/or may be a flexible IC.

Also disclosed herein is a method for manufacturing an electronic circuit comprising a semiconductor body for a p-type TFT, the method comprising: depositing one or more layers of amorphous silicon (a-Si) on a substrate, crystallising the one or more layers of amorphous silicon, patterning the one or more layers of crystallised amorphous silicon to provide, at least, a semiconductor body having a channel length of from 0.05 to 0.6 μm.

Also disclosed herein is a method of manufacturing an electronic circuit comprising a p-type TFT comprises: depositing one or more layers of amorphous silicon on a substrate, crystallising the one or more layers of amorphous silicon, patterning the one or more layers of crystallised amorphous silicon to provide, at least, a first semiconductor body, and forming a p-type TFT having a channel region formed from the semiconductor body and having a channel length of from 0.5 to 20 μm.

The channel length may be from 0.1 to 19.5 μm, for example, from 0.15 to 18.5 μm, 0.2 to 18 μm, 0.25 to 17.5 μm, 0.3 to 17 μm, 0.35 to 16.5 μm, 0.4 to 16 μm, 0.45 to 15.5 μm, 0.5 to 15 μm, 0.55 to 14.5 μm, 0.6 to 14 μm, 0.65 to 13.5 μm, 0.7 to 13 μm, 0.75 to 12.5 μm, 0.8 to 12 μm, 0.85 to 11.5 μm, 0.9 to 11 μm, 0.95 to 10 μm, or 1 to 9.5 μm.

The channel length may be from 0.05 to 9 μm, such as, for example, from 0.055 to 5 μm, 0.1 to 4.5 μm, 0.15 to 4 μm, 0.2 to 3.5 μm, 0.25 to 3 μm, 0.3 to 2.5 μm, 0.35 to 2 μm, 0.4 to 1.5 μm. For example, the channel length may be from 0.05 to 0.6 μm, for example, from 0.1 to 0.55 μm, 0.15 to 0.5 μm, 0.2 to 0.45 μm, 0.25 to 0.4 μm, 0.3 to 0.35 μm.

The p-type TFT may have a channel region and/or source and drain regions that are formed of doped LTPS. The doping may, for example, comprise one or more of phosphorous ions, BF₂ ions, or any other dopants or doping ions known to the person skilled in the art.

The channel region of the p-type TFT may have a charge carrier mobility of between 1 and 200 cm²/V·s.

The channel region of the p-type TFT may have a charge carrier mobility of from 0.5 and 200 cm²/V·s, for example, from 1.5 to 195 cm²/V·s, 2 to 190 cm²/V·s, 2.5 to 185 cm²/V·s, 3 to 180 cm²/V·s, 3.5 to 175 cm²/V·s. 4 to 170 cm²/V·s, 5 to 165 cm²/V·s, 5.5 to 160 cm²/V·s, 6 to 155 cm²/V·s, 6.5 to 150 cm²/V·s, 7 to 145 cm²/V·s, 7.5 to 140 cm²/V·s, 8 to 135 cm²/V·s, 8 to cm²/V·s, 130 cm²/V·s, 8.5 to 125 cm²/V·s, 9 to 120 cm²/V·s, 9.5 to 115 cm²/V·s, 10 to 110 cm²/V·s, 10.5 to 105 cm²/V·s, 11 to 100 cm²/V·s, 11.5 to 95 cm²/V·s, 12 to 90 cm²/V·s, or 12.5 to 85 cm²/V·s.

The charge carrier mobility of the LTPS may, for example, have charge mobility of from 1 to 40 cm²/V·s, such as, for example, 1.5 to 39 cm²/V·s, 2 to 38 cm²/V·s, 2.5 to 37 cm²/V·s, 3 to 36 cm²/V·s, 3.5 to 35.5 cm²/V·s, 4 to 35 cm²/V·s, 4.5 to 35 cm²/V·s, 5 to 34 cm²/V·s, 5.5 to 33 cm²/V·s, 6 to 32 cm²/V·s, 6.5 to 31 cm²/V·s, 7 to 30 cm²/V·s, 7.5 to 29 cm²/V·s, 8 to 28 cm²/V·s, 8.5 to 27 cm²/V·s, 9 to 26 cm²/V·s, 9.5 to 25 cm²/V·s, 10 to 24 cm²/V·s, or 11 to 23 cm²/V·s.

The channel region of the p-type TFT may have a charge carrier mobility of from 1 to 30 cm²/V·s, such as, for example, 1.5 to 29 cm²/V·s, 2 to 28 cm²/V·s, 2.5 to 27 cm²/V·s, 3 to 26 cm²/V·s, 3.5 to 25.5 cm²/V·s, 4 to 25 cm²/V·s, 4.5 to 25 cm²/V·s, 5 to 24 cm²/V·s, 5.5 to 23 cm²/V·s, 6 to 22 cm²/V·s, 6.5 to 21 cm²/V·s, 7 to 20 cm²/V·s, 7.5 to 19 cm²/V·s, 8 to 18 cm²/V·s, 8.5 to 17 cm²/V·s, 9 to 16 cm²/V·s, 9.5 to 15 cm²/V·s, 10 to 14 cm²/V·s, or 11 to 13 cm²/V·s.

The amorphous silicon may be doped or undoped a-Si.

The method of manufacturing an electronic circuit may comprise depositing a layer of doped amorphous silicon on a substrate, patterning the layer of (undoped) amorphous silicon to form to a first terminal region and a second terminal region, depositing a layer amorphous silicon over the first terminal region and the second terminal region, crystallising the layers of amorphous silicon, and patterning the crystallised layers of polysilicon to provide a semiconductor body having a channel extending between the first and second terminal regions.

In the described examples, amorphous silicon is deposited and subsequently crystallised. For example, as described above in relation to FIGS. 1A to 1F, in one exemplary method for the manufacture of an electronic circuit in accordance with the present disclosure, a layer of amorphous silicon is deposited on a substrate, and subsequently crystallised and patterned to form a semiconductor body, having a channel length of from 0.5 to 20 μm. The amorphous silicon may be deposited by Plasma Enhanced Chemical Vapour Deposition (PECVD). Crystallisation the amorphous silicon may be performed, for example, by one or more of: laser annealing, excimer laser annealing (ELA), blue laser annealing (BLA), single area excimer laser crystallisation (SAELC), U crystallisation, selective laser sintering, metal induced crystallisation (MIC), metal induced lateral crystallisation, and continuous granular crystalline silicon.

In the described examples, layers of various materials (including semiconducting, insulating, and conducting materials) are formed and patterned. For example, as described above in relation to FIGS. 1A to 1F, an insulating layer is subsequently deposited over the semiconductor body, and the substrate. A gate electrode is formed over the semiconductor body, on the insulating layer.

It will be appreciated that the various materials may be deposited in layers and patterned using known thin-film deposition and lithographic techniques. For example, materials may be deposited in layers by a technique, such as vapour deposition (physical, e.g. sputter or chemical, e.g. PECVD), vacuum deposition (e.g. thermal or e-beam evaporation); coating (spin, dip, blade, bar, spray, slot-die), printing (jet, gravure, offset, screen, flexo), pulsed-laser deposition (PLD), atomic layer deposition (ALD) and/or other currently known techniques. Patterning of deposited materials may be performed by CBD (coat, bake, develop) and photo-lithography (i.e. exposure), electron beam lithography, X-ray lithography, ion-beam lithography, printing and/or other currently known techniques. The patterning may be combined, where applicable, with wet and/or dry (plasma) etching, ablation, milling, and/or lift-off patterning.

The gate electrodes described herein, for any of the examples may, for example, be formed from a material selected from one or more of: Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnₓO_{y}N_{z}; inorganic semiconductors, such as amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃.

It can be seen that, the crystallised amorphous silicon semiconductor body may, for example, be an LTPS island as described herein. This crystallised amorphous silicon semiconductor body is irradiated, and the gate electrode is used as mask to shield a region of the crystallised amorphous silicon semiconductor body, to form a channel region of the p-type TFT, such that the areas at the crystallised amorphous semiconductor body's terminus are exposed and become more conductive/less resistive than the shielded (channel) region of the crystallised amorphous semiconductor body. The exposed areas at the termini may thus serve as the first and second terminals (e.g., source and drain terminals) of the p-type TFT.

As described above, the irradiation may comprise irradiating the crystallised amorphous semiconductor body with a source of UV light. The source of UV light may be an excimer lamp or excimer laser. The source of UV light may, for example, emit UV light at a wavelength of from 190 to 1100 nm, such as for example from 193 to 1064 nm, 193 to 355 nm, 350 to 500 nm, 355 to 495 nm, or 266 to 350 nm. The source of UV light may be a solid state, or pulsed excimer Nd:YAG lasers, XeCl and KrF pulsed excimer lasers, CW green lasers, and CW diode laser. Methods for annealing semiconductor materials are known to the person skilled in the art, and are, for example, provided WO 2012/131395 A1, and Proc. of SPIE Vol. 8968, 89680U (6 Mar. 2014), which are incorporated herein by reference.

As described herein, an etch-stop layer, may be deposited and formed on the gate electrode(s), and through vias may be formed in the insulating layer(s). A layer of conducting material may then be deposited and patterned to form various contacts (and/or source and drain electrodes) in the vias. The etch-stop layer may, for example, be formed from etch-stop materials commonly known to the person skilled in the art such as, for example, metal nitrides, such as, TiN, TaN, among others.

The contacts and/or the source and the drain electrodes may be formed from layers of one more conductive or semiconductive materials selected from one or more of: Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnₓO_{y}N_{z}; inorganic semiconductors, such as amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃.

As described with reference to FIGS. 1A to 1F in particular, in one exemplary method for the manufacture of an electronic circuit in accordance with the present disclosure, an electronic circuit is fabricated in which a p-type TFT and an associated resistor are formed using the same material. Specifically, referring to FIG. 1A, a layer of amorphous silicon is deposited a substrate 103, and subsequently crystallised and patterned to form a first semiconductor body 101, and a second semiconductor body 102, each having a p-type semiconductor body length of from 0.05 to 0.6 μm. Then, as seen in FIG. 1B, an insulating layer 104 is subsequently deposited over the first semiconductor body 101 and the second semiconductor body 102, and the substrate 103. Then, as seen in FIG. 1C, a gate electrode 105 is formed over the first semiconductor body 101, on insulating layer 104.

These semiconductor bodies 101, 102 are then irradiated. In the case of the first semiconductor body 101, the gate electrode acts as mask to shield the channel of the semiconductor body, such that the areas at the semiconductor body's terminus 106a, 106b are exposed and become more conductive/less resistive than the channel of the semiconductor body 101. The exposed areas at the termini may thus serve as the first and second terminals 106a, 106b of the p-type TFT, as seen in FIG. 1D. The second semiconductor body 102 (for forming the resistor) is fully exposed to the irradiation and forms a more conductive/less resistive semiconductor body 106c than the original crystallised amorphous silicon semiconductor body 102. Subsequently, an etch-stop layer 107 is deposited and formed on the gate electrode 105, and through vias 108a, 108b, 108c, and 108d are formed in the insulating layer 104, as seen in FIG. 1E. A layer of conducting material is then deposited and patterned to form contacts (or source and drain electrodes) 109a, 109b, 109c, and 109d in the vias 108a-d, as seen in FIG. 1F.

As described with reference to FIGS. 2A to 2F in particular, in one exemplary method for the manufacture of an electronic circuit in accordance with the present disclosure, an electronic circuit comprising a p-type TFT and an n-type TFT are formed. Referring to FIG. 2A, a layer of amorphous silicon is deposited a substrate 203, and subsequently crystallised and patterned to form a first semiconductor body 201 having a channel length of from 0.5 to 20 μm. A layer of semiconducting material, such as metal oxide semiconductor, is deposited and patterned to form a second, n-type TFT, semiconductor body 202.

The second, n-type TFT, semiconductor bodies may be formed from semiconductor materials selected from one or more of: GaAs, GaN, InP, CdSe, InGaAs, InGaAsSb, metal oxides, such as, ZnO, SnO₂, NiO, SnO, Cu₂O, In₂O₃, LiZnO, ZnSnO, InSnO (ITO), InZnO (IZO), HfInZnO (HIZO), InGaZnO (IGZO); metal oxynitrides, e.g. ZnxOyNz; inorganic semiconductors, such as, amorphous, microcrystalline or nanocrystalline Si; organic semiconductors, such as, CuPc, pentacene, PTCDA, methylene blue, Orange G, rubrene; polymer semiconductors, such as, PEDOT:PSS, POT, P₃OT, P₃HT, polyaniline, polycarbazole; 2D materials, such as, graphene; chalcogenides, such as, MoS₂, GeSbTe; and perovskites, such as, SrTiO₃, CH₃NH₃PbCl₃, H₂NCHNH₂PbCl₃, CsSnI₃. These semiconductor materials may also be doped or contain a doping gradient. Further treatments may be applied to the component layers to modify their semiconductor properties such as annealing (thermal, laser). In some embodiments, the n-type resistor bodies may be formed from IGZO.

As seen in FIG. 2B, an insulating layer 204 is subsequently deposited over the first semiconductor body 201 and second semiconductor body 202, and the substrate 203. In FIG. 2C, gate electrodes 205a, 205b are formed over the semiconductor body 201 and second semiconductor body 202 respectively, on insulating layer 204.

The first semiconductor body 201 and the second, n-type TFT, semiconductor body 202 are then irradiated. The gate electrodes 205a and 205b act as masks to shield the channel of the respective semiconductor (and any resistor) bodies, such that the areas at the semiconductor bodies' termini 206a, 206b, 206c, 206d are exposed and become more conductive/less resistive than the channel region or semiconductor body of the respective first and second semiconductor bodies 201, 202. The exposed areas at the termini may thus serve as the first and second terminals 206a, 206b of the p-type TFT (crystalized amorphous silicon semiconductor body, first semiconductor body), and the second and third terminals 206c, 206d of the n-type TFT (n-type TFT semiconductor body, second semiconductor body, metal oxide semiconductor body) respectively, as seen in FIG. 2D.

Subsequently, an etch-stop layer 207 is deposited and formed on the gate electrodes 205a and 205b, and through vias 208a-d are formed in the insulating layer 204, FIG. 2E. A layer of conducting material is then deposited and patterned to form contacts (or source and drain electrodes) 209a-d in the vias 208a-d, as seen in FIG. 2F.

As described with reference to FIGS. 4A to 4F in particular, in one exemplary method for the manufacture of an electronic circuit in accordance with the present disclosure, another electronic circuit comprising a p-type TFT, an n-type TFT is formed. Referring to FIG. 4A, a layer of amorphous silicon is deposited a substrate 403, and subsequently crystallised and patterned to form a first semiconductor body 401, having a channel length of from 0.5 to 20 μm. An insulating layer 404a is subsequently deposited over the first semiconductor body 401, and the substrate 403.

A layer of semiconducting oxide material, such as metal oxide semiconductor, is deposited and patterned on insulator layer 404a to form a second, n-type TFT, semiconductor body 402. A second insulator layer 404b is then deposited over the second, n-type TFT, semiconductor body 402, FIG. 4B.

In FIG. 4C, gate electrodes 405a, 405b are formed over the first semiconductor body 401 and second, n-type TFT, semiconductor body 402 respectively, on insulating layers 404a and 404b respectively.

The insulating layers 404a and 404b may be formed from the same source material. Insulating layers 404a and 404b may, nevertheless, be formed from different source materials. The insulating layers 404a and 404b may be formed from the same or different materials.

The first semiconductor body 401 and the second, n-type TFT, semiconductor body 402 are then irradiated. The gate electrodes 405a and 405b act as masks to shield the channel of the respective resistor bodies, such that the areas at the resistor bodies' termini 406a, 406b, 406c, 406d are exposed and become more conductive/less resistive than the channel or semiconductor body of the respective first and second semiconductor bodies 401, 402. The exposed areas at the termini may thus serve as the first and second terminals 406a, 406b of the p-type TFT (crystallised amorphous silicon semiconductor body, first semiconductor body), and the second and third terminals 406c, 406d of the n-type TFT (n-type TFT semiconductor body, second semiconductor body, metal oxide semiconductor body) respectively, as seen in FIG. 4D.

Subsequently, an etch-stop layer 407 is deposited and formed on the gate electrodes 405a and 405b, and through vias 408a-d are formed in the insulating layer 404a, FIG. 4E. A layer of conducting material is then deposited and patterned to form contacts (or source and drain electrodes) 409a-d in the vias 408a-d, as seen in FIG. 4F.

As described with reference to FIGS. 3A to 3F in particular, in one exemplary method for the manufacture of an electronic circuit in accordance with the present disclosure, an electronic circuit comprising a p-type TFT, and a SIMCap is formed. Referring to FIG. 3A, a layer of amorphous silicon is deposited a substrate 303, and subsequently crystallised and patterned to form a first semiconductor body 301 and second semiconductor body 302.

In FIG. 3B, an insulating layer 304 is subsequently deposited over the first semiconductor body 301, the second semiconductor body 302, and the substrate 303. In FIG. 3C, gate electrode 305 is formed over the first semiconductor body 301, on insulating layer 304.

The first semiconductor body 301 and the second semiconductor body 302 are then irradiated. Gate electrode 305 acts as mask to shield the channel of the first semiconductor body, such that the areas at the first semiconductor body's termini 306a, 306b are exposed and become more conductive/less resistive than the channel region of the first semiconductor body 301. The exposed areas at the termini may thus serve as the first and second terminals 306a, 306b of the p-type TFT (crystallised polysilicon semiconductor body, first semiconductor body). The second semiconductor body 302 (for forming a plate of the capacitor) is fully exposed to the irradiation and forms a more conductive/less resistive semiconductor body 306c than the original crystallised polysilicon semiconductor body 302, as seen in FIG. 3D.

Subsequently, an etch-stop layer 307 is deposited and formed on the gate electrode 305, and through vias 308a-c are formed in the insulating layer 304, as seen in FIG. 3E. A layer of conducting material is then deposited and patterned to form contacts (or source and drain electrodes) 309a, b and d in the vias 308a, b, and d, as seen in FIG. 3F. The capacitor contact 309c also serves as a capacitor top plate and is provided at least partially over the second semiconductor body 306c, which serves as a conductive lower plate. Capacitor contact 309d makes electrical contact with the lower capacitor plate 306c.

The top contact for the SIMCap, such as top contact 309c may be formed from one or more of: LTPS, doped LTPS, Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; or semiconductor materials.

As described with reference to FIGS. 5A to 5E in particular, in one exemplary method for the manufacture of an electronic circuit in accordance with the present disclosure, an electronic circuit comprising a p-type TFT, an n-type transistor and a MIMCap. Referring to FIG. 5A, a layer of a-Si (amorphous silicon) is deposited a substrate 503, and subsequently crystallised and patterned to form a first semiconductor body 501, having a channel length of from 0.05 to 0.6 μm. An insulating layer 504a is subsequently deposited over the crystallised polysilicon semiconductor body 501, and the substrate 503.

A layer of semiconducting material, such as metal oxide semiconductor, is deposited and patterned on insulator layer 504a to form a second, n-type TFT, semiconductor body 502. Gate electrode 505a is formed over the first semiconductor body 501, on insulating layer 504; source and drain electrodes (or contacts) 509c, 509d for the second, n-type TFT, semiconductor body 502 are formed, and a MIMcap lower electrode plate 513 is formed (not shown), as seen in FIG. 5B.

In FIG. 5C, an etch-stop layer 507 is deposited and formed on the gate electrode 505, source and drain electrodes 509a, 509b, and the MIMcap lower electrode plate 513 (not shown). Through vias 508a and 508b are formed in the insulating layer 504.

The first semiconductor body 501 and the second, n-type TFT, semiconductor body 502 are then irradiated. Gate electrode 505 acts as mask to shield the channel of the first semiconductor body 501, such that the areas at the semiconductor body's termini 506a, 506b are exposed and become more conductive/less resistive than the channel of the crystallised amorphous silicon first semiconductor body 501. The exposed areas at the termini may thus serve as the first and second terminals 506a, 506b of the p-type TFT (crystallised amorphous silicon semiconductor body, first semiconductor body). The second semiconductor body 502 (of the n-type transistor) is fully exposed to the irradiation, however the wavelength of the source irradiation is selected such that the material of the second, n-type TFT, semiconductor body is transparent to such irradiation, as seen in FIG. 5D. For example, the irradiation wavelength and second, n-type TFT, semiconductor body material may be selected such that the electrical properties of the first semiconductor body are changed by such irradiation but the material of the second, n-type TFT, semiconductor body is not. For example, metal oxide semiconductors such as IGZO are substantially transmissive of wavelengths of greater than ~300 nm, whereas the electrical properties of the crystallised amorphous silicon are affected by UV irradiation at wavelengths of from 300 nm. In one example irradiation from a green laser may be used, for example having a wavelength of 532 nm.

Subsequently, a source and drain electrode for the crystallised a-Si semiconductor body 509a, 509b are formed, along with a top gate electrode for the n-type transistor 505b, and a top plate contact for the MIMcap 505c, as seen in FIG. 5E.

In some embodiments, the top contact for a MIMCap, such as top contact 309c may be formed from one or more of: LTPS, doped LTPS, Au, Ti, Al, Mo, Pt, Pd, Ag, Cu, Ni, Cr, Ta, W; metal alloys, such as, MoNi, MoCr, AlSi; transparent conductive oxides, such as, ITO, IZO, AZO; metal nitrides, such as, TiN; carbon materials, such as, carbon black, carbon nanotubes, graphene; conducting polymers, such as, polyaniline, PEDOT:PSS; or semiconductor materials.

Methods for manufacturing p-type transistors have shown been in: Schalberger et al., IMID/IDMC Digest, p. 1645-1648, (2006); Baur et al., Society for Information Display (SID) digest, May 2005, Vol. 36, Issue 1, pages 1266-1269; and Schalberger et al., Society for Information Display (SID) digest, May 2010, Vol. 41, Issue 1, pages 909-912, which are incorporated herein by reference. For example, the method of the present disclosure may comprise depositing a high doped layer of silicon onto a substrate, for example, a highly phosphorous doped silicon. Using patterning techniques known the person skilled in the art, the layer of highly doped silicon is patterned to provide islands where the source and drain electrodes will later be formed onto the p-type TFT. Subsequently, amorphous silicon is deposited over the islands and the substrate and subsequently dehydrogenated at 450 °C and crystallised, for example, using single area excimer laser crystallisation (SAELC). Without wishing to be limited by theory, it is considered that during crystallization, some of phosphorous in the islands may laterally diffuse across to the amorphous silicon resulting in a low doped drain (LDD) structure at either terminus of the amorphous silicon structure (amorphous silicon once crystallised). The resultant polysilicon layer is then patterned, and a silane based oxide subsequently deposited and patterned.

Throughout the specification, the term “connected” is understood to mean a direct connection such as electrical, mechanical or magnetic connection between the things that are connected. The term “coupled” is understood to mean a direct or indirect connection (i.e. through one or more passive or active intermediary devices). The term “scaling” may be understood to generally refer to converting one layout pitch to another layout pitch. Further, unless otherwise specified, the use of ordinal adjectives, such as, “first”, “second”, “third” etc. merely indicate that different instances of like objects are being referred to and are not intended to imply that the objects so described must be in a given sequence, either temporally, spatially, in ranking or in any other manner. Orientation terminology, such as, “horizontal” is understood with respect to a plane parallel to the conventional plane or surface of a wafer or substrate, regardless of the orientation of the wafer or substrate. The term “vertical” may refer to a direction perpendicular to the horizontal as defined previously. Prepositions, such as, “on”, “side”, “higher”, “upper”, “lower”, “over”, “bottom” and “under” may be understood with respect to the conventional plane or surface being on the top surface of the wafer or substrate, regardless of the orientation the electrical interconnects or the electronic package.

The figures of this specification are not limited to the elements illustrated therein but may include further elements or elements may be omitted. The figures are also not to scales and the size of certain elements are exaggerated for illustrative purposes.

Throughout the description and claims of this specification, the words “comprise” and “contain” and variations of them mean “including but not limited to”, and they are not intended to (and do not) exclude other components, integers, or steps. Throughout the description and claims of this specification, the singular encompasses the plural unless the context otherwise requires. In particular, where the indefinite article is used, the specification is to be understood as contemplating plurality as well as singularity, unless the context requires otherwise.

As used herein, the terms “A, B or C” or “at least one of A, B and/or C”, or the like, may include all possible combinations of A, B and C. It will be understood that when an element (e.g., a first element) is referred to as being (operatively or communicatively) “coupled with/to” or “connected with/to” another element (e.g., a second element), it can be coupled or connected with/to the other element directly or via one or more other elements.

Features, integers, characteristics, or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

1. An integrated circuit (IC) comprising:
at least one p-type thin film transistor, ‘TFT’, and at least one further electronic device, formed on a substrate;
wherein the at least one p-type TFT comprises a channel region formed from at least partially crystalline silicon, wherein the partially crystalline silicon has been formed from amorphous silicon using a process that maintains the substrate at a temperature below 650 °C; and
wherein, the channel region of the at least one p-type TFT is formed of at least partially crystalline silicon that has a charge carrier mobility within the range of 1 to 40 cm²/V·s inclusive.

2. An integrated circuit (IC) comprising:
at least one p-type thin film transistor, ‘TFT’, and at least one further electronic device, fabricated on a substrate;
wherein the at least one p-type TFT comprises a channel region formed from at least partially crystalline silicon, wherein the partially crystalline silicon has been formed from amorphous silicon using a process that maintains the substrate at a temperature below 650 °C; and
wherein the at least one further electronic device comprises at least one n-type TFT, wherein the at least one n-type TFT comprises a channel region formed from semiconducting oxide.

3. The IC of claim 1, wherein the at least one further electronic device comprises at least one n-type TFT, wherein the at least one n-type TFT comprises a channel region formed from semiconducting oxide.

4. The IC of claim 2 or 3, wherein the channel region of the at least one p-type TFT is formed of at least partially crystalline silicon that has a charge carrier mobility that is within a range of 1 to 20, optionally within a range to 1 to 15, a range of 1 to 10, or a range of 1 to 5, times a charge carrier mobility of the semiconducting oxide from which the channel region of the at least one n-type TFT is formed.

5. The IC of any of claims 2 to 4, wherein the at least one p-type TFT has a first channel length and the at least one n-type TFT has a second channel length, and wherein the first channel length is greater than the second channel length.

6. The IC of claim 5, wherein the second channel length is less than 0.6 μm in length.

7. The IC of any of claims 5 to 6, wherein the first channel length and the second channel length are mutually configured to ensure that a lowest value of a first maximum drain source current for a given gate voltage magnitude for the p-type device, and a second maximum drain source current for the given gate voltage magnitude for the n-type device is within 25% of the highest value of the first maximum drain source current and the second maximum drain source current.

8. The IC of claim 7, wherein the first channel length and the second channel length are mutually configured to ensure that the second maximum drain source current is the same as or greater than the second maximum drain source current.

9. The IC of any of claims 5 to 8, wherein the first channel length is greater than 1 μm in length and the second channel length is less than 1 μm in length.

10. The IC of any of claims 2 to 8, wherein a channel length, or the first channel length, of the at least one p-type TFT is between 0.05 μm and 0.6 μm.

11. The IC of any of claims 2 to 10, wherein the at least one p-type TFT has a p-type TFT gate insulator, and the at least one n-type TFT has an n-type TFT gate insulator that is formed of a different insulator layer to the first gate insulator.

12. The IC of claim 11, wherein the p-type TFT gate insulator is of a first thickness and the n-type TFT gate insulator is of a second thickness that is different to the first thickness.

13. The IC of claim 12, wherein the first thickness and second thickness are mutually configured to ensure that a lowest value of a first parasitic capacitance associated with the p-type TFT gate insulator, and a second parasitic capacitance associated with the n-type TFT gate insulator, is within 20% of a highest value of the first parasitic capacitance and the second parasitic capacitance.

14. The IC of any of claims 11 to 13, wherein the p-type TFT first gate insulator is of a first material having a first dielectric constant and the n-type TFT gate insulator is of a second material having a second dielectric constant that is different to the first dielectric constant.

15. The IC of claim 14, wherein the first material has a first dielectric constant and the second material has a second dielectric constant, and the first dielectric constant and the second dielectric constant are mutually configured to ensure that a lowest value of a first parasitic capacitance associated with the p-type TFT gate insulator and a second parasitic capacitance associated with the n-type TFT gate insulator, is within 20% of a highest value of the first parasitic capacitance and the second parasitic capacitance.

16. The IC of any of claims 2 to 15, wherein the at least one further electronic device comprises at least one resistor formed from a semiconducting oxide forming part of a fabrication layer that is common with the semiconducting oxide from which the channel region of the n-type TFT is formed.

17. The IC of any of claims 2 to 8, wherein the at least one p-type TFT and the at least one n-type TFT have respective gate insulators that are formed of the same insulator layer.

18. The IC of any of claims 2 to 17, wherein the at least one semiconducting oxide, from which the channel region of the n-type TFT is formed, is provided directly on the substrate or on a barrier layer formed directly on the substrate.

19. The IC of any of claims 2 to 17, wherein the at least one semiconducting oxide, from which the channel region of the n-type TFT is formed, is formed on an insulating layer that is provided between the substrate and the at least one semiconducting oxide.

20. The IC of any of claims 2 to 18, wherein a source region and a drain region of the at least one n-type TFT are formed at either end of the channel region from the at least one semiconducting oxide.

21. The IC of claim 20, wherein the source region and the drain region of the at least one n-type TFT are formed from respective regions of the at least one semiconducting oxide that have been irradiated with electro-magnetic radiation to change an electrical property of those regions of the at least one semiconducting oxide to make the regions of the at least one semiconducting oxide conductive.

22. The IC of any of claims 2 to 21, wherein the at least one semiconducting oxide is a metal oxide semiconductor.

23. The IC of any of claims 2 to 22, wherein the at least one semiconducting oxide is indium gallium zinc oxide, ‘IGZO’.

24. The IC of any of claims 2 to 23, wherein the at least one p-type thin film transistor, ‘TFT’, and the at least one n-type thin film transistor are interconnected to form a circuit comprising at least one complementary metal oxide semiconductor, ‘CMOS’, circuit.

25. The IC of claim 24, wherein the at least one CMOS circuit comprises at least one CMOS inverter circuit.

26. The IC of any of claims 1 to 25, wherein the at least partially crystalline silicon, from which the channel region of the p-type TFT is formed, is formed directly on the substrate or on a barrier layer formed directly on the substrate.

27. The IC of any of claims 1 to 26, wherein a source region and a drain region of the at least one p-type TFT are formed at either end of the channel region from the at least partially crystalline silicon.

28. The IC of claim 27, wherein the source region and the drain region of the at least one p-type TFT are formed from respective regions of the at least partially crystalline silicon that have been irradiated with electro-magnetic radiation to change an electrical property of the partially crystalline silicon of those regions of the at least partially crystalline silicon to make those regions of the at least partially crystalline silicon more conductive.

29. The IC of claim 27 or 28, wherein the source region and the drain region of the at least one p-type TFT are formed from respective regions of the at least partially crystalline silicon that have been doped to change an electrical property of the partially crystalline silicon of those regions of the at least partially crystalline silicon to make those regions of the at least partially crystalline silicon more conductive.

30. The IC of any of claims 1 to 29, wherein the at least partially crystalline silicon comprises polycrystalline silicon.

31. The IC of claim 30, wherein the polycrystalline silicon is low temperature polycrystalline silicon, ‘LTPS’.

32. The IC of any of claims 1 to 31, wherein the at least partially crystalline silicon has been formed from amorphous silicon using a laser.

33. The IC of claim 32, wherein the at least partially crystalline silicon has been formed from amorphous silicon using an excimer laser, or a blue light-emitting diode (LED), or a blue solid state laser.

34. The IC of any of claims 1 to 33, wherein the at least one further electronic device comprises at least one resistor.

35. The IC of claim 34, wherein the at least one resistor comprises at least one resistor formed from at least partially crystalline silicon.

36. The IC of claim 35, wherein the at least one resistor comprises at least one resistor formed from at least partially crystalline silicon forming part of a fabrication layer that is common with the at least partially crystalline silicon from which the channel region of the at least one p-type TFT is formed.

37. The IC of any of claims 34 to 36, wherein the at least one resistor comprises at least one resistor formed from a semiconducting oxide material.

38. The IC of any of claims 1 to 37, wherein the at least one further electronic device comprises at least one capacitor comprising comprises a first capacitor plate, a second plate formed of metal, and a capacitor insulator provided between the first capacitor plate and the second capacitor plate.

39. The IC of claim 38, wherein the at least one capacitor comprises at least one capacitor for which the first capacitor plate is formed from a semiconductor material, and the second plate is formed of a metal material.

40. The IC of claim 39, wherein the first capacitor plate is formed from at least partially crystalline silicon that is of the same type as the at least partially crystalline silicon from which the channel region of the at least one p-type TFT is formed.

41. The IC of any of claims 38 to 40, wherein the at least one capacitor comprises at least one capacitor for which the first capacitor plate and the second plate are each formed of a respective metal material.

42. The IC of any of claims 1 to 41, wherein the substrate is a flexible substrate.

43. The IC of claim 42, wherein the substrate is formed of polyimide.

44. The IC of any of claims 1 to 41, wherein the substrate is a rigid substrate.

45. The IC of claim 42 or 44, wherein the substrate is formed of glass.

46. The IC of any of claims 1 to 45, wherein a barrier layer is formed on the substrate.

47. A method of fabricating an integrated circuit (IC), the method comprising:
providing a substrate and fabricating the IC on the substrate, the IC comprising at least one p-type thin film transistor, ‘TFT’, and at least one further electronic device;
wherein the at least one p-type TFT is fabricated by:
forming a first layer, the first layer comprising amorphous silicon;
processing the first layer to convert the amorphous silicon into at least partially crystalline silicon using a process that maintains the substrate at a temperature below 650 °C;
patterning the first layer, before or after conversion to the at least partially crystalline silicon, to form at least one semiconductor area; and
fabricating the at least one p-type TFT wherein the channel region of the at least one p-type TFT is formed from the at least partially crystalline silicon of the at least one semiconductor area;
wherein, the processing of the first layer is configured to produce partially crystalline silicon, in the at least one semiconductor area that forms the channel region of the at least one p-type TFT, that has a charge carrier mobility within the range of 1 to 40 cm²/V·s inclusive when the at least one p-type TFT has been fabricated.

48. A method of fabricating an integrated circuit (IC), the method comprising:
providing a substrate and fabricating the IC on the substrate, the IC comprising at least one p-type thin film transistor, ‘TFT’, and at least one further electronic device;
wherein the at least one p-type TFT is fabricated by:
forming a first layer, the first layer comprising amorphous silicon;
processing the first layer to convert the amorphous silicon into at least partially crystalline silicon using a process that maintains the substrate at a temperature below 650 °C;
patterning the first layer, before or after conversion to the at least partially crystalline silicon, to form at least one semiconductor area; and
fabricating the at least one p-type TFT wherein the channel region of the at least one p-type TFT is formed from the at least partially crystalline silicon of the at least one semiconductor area;
wherein the at least one further electronic device comprises an n-type TFT, wherein the at least one n-type TFT is fabricated by:
forming a second layer, the second layer comprising a semiconducting oxide;
patterning the second layer to form at least one semiconducting oxide area; and
fabricating the at least one n-type TFT wherein a channel region of the at least one n-type TFT is formed from the semiconducting oxide of the at least one semiconducting oxide area.

49. The method of claim 47, wherein the at least one further electronic device comprises an n-type TFT, wherein the at least one n-type TFT is fabricated by:
forming a second layer, the second layer comprising a semiconducting oxide;
patterning the second layer to form at least one semiconducting oxide area; and
fabricating the at least one n-type TFT wherein a channel region of the at least one n-type TFT is formed from the semiconducting oxide of the at least one semiconducting oxide area.

50. The method of claim 49, wherein the processing of the first layer is configured to produce partially crystalline silicon, in the at least one semiconductor area that forms the channel region of the at least one p-type TFT, that has a charge carrier mobility that is within a range of 1 to 20, optionally within a range of 1 to 15, a range of 1 to 10, or a range of 1 to 5, times a charge carrier mobility of the semiconducting oxide from which the channel region of the at least one n-type TFT is formed.

51. The method of any of claims 47 to 50, wherein the at least one p-type thin film transistor, ‘TFT’, and the at least one n-type thin film transistor are interconnected to form a circuit comprising at least one complementary metal oxide semiconductor, ‘CMOS’, circuit.

52. The IC of claim 51, wherein the at least one CMOS circuit comprises at least one CMOS inverter circuit.

53. A method of fabricating an integrated circuit (IC), the method comprising providing a substrate and fabricating an IC according to any of claims 1 to 46 on the substrate from a plurality of layers.
